(19) United States
(12) Patent Application Publication
(10) Pub. No.: US 2024/0234230 A1
(43) Pub. Date: Jul. 11, 2024

(54) ELECTRONIC DEVICE

(71) Applicant: Rohm Co., Ltd., Kyoto-shi (JP)

(72) Inventors: Natsuki SAKAMOTO, Kyoto-shi (JP); Hiroyuki SHINKAI, Kyoto-shi (JP)

(21) Appl. No.: 18/617,040

(22) Filed: Mar. 26, 2024

Related U.S. Application Data
(63) Continuation of application No. PCT/JP2022/035702, filed on Sep. 26, 2022.

(30) Foreign Application Priority Data
Oct. 4, 2021 (JP) 2021-163439

(51) Int. Cl. H01L 23/31; H01L 23/00; H01L 23/498

(52) U.S. Cl. CPC H01L 23/3121; H01L 23/49838; H01L 24/32; H01L 24/94; H01L 2224/32238; H01L 2224/94; H01L 2924/1815

(57) ABSTRACT

An electronic device includes an electronic component, a resin member covering the electronic component, and a conductive member supported by the resin member. The resin member includes a first resin side surface and a second resin side surface that intersect with each other. The conductive member includes a first corner terminal including a first exposed surface exposed from the first resin side surface and a second exposed surface exposed from the second resin side surface. The first corner terminal includes a first surface connected to the first exposed surface and the second exposed surface as viewed in a thickness direction of the resin member. The first surface is covered with the resin member.

### TECHNICAL FIELD

The present disclosure relates to an electronic device.

### BACKGROUND ART

Conventionally, there have been electronic devices in leadless packages, such as small outline non-leaded packages (SON packages) and quad flat non-leaded packages (QFN packages). Such a leadless-package electronic device is advantageous for downsizing and thinning because no terminals for external connection protrude from a sealing resin that seals electronic components. For example, JP-A-2008-112961 discloses a leadless package semiconductor device including an electronic component (semiconductor chip).

The semiconductor device disclosed in JP-A-2008-112961 includes a semiconductor chip, a plurality of leads, and a sealing resin. The leads are conductive members, and are made of copper, for example. The leads are electrically connected to the semiconductor chip, and serve as the above-described external connection terminals when the semiconductor device is mounted on the circuit board of an electronic device or the like. The leads are supported by the sealing resin by adhering to the sealing resin, for example. The sealing resin covers the semiconductor chip. Such a semiconductor device is manufactured by a molded array packaging (MAP) method, for example. According to the MAP method, a plurality of semiconductor chips on a lead frame are collectively sealed by a sealing resin, and the lead frame is diced into pieces each including a single semiconductor chip. As a result of the dicing, a portion of the lead frame (a portion of each lead) is exposed from the sealing resin, and the exposed portion forms an external connection terminal.

### BRIEF DESCRIPTION OF THE DRAWINGS

FIG. 1 is a perspective view showing an electronic device according to a first embodiment, seen from a bottom surface side.

FIG. 2 is a plan view showing the electronic device according to the first embodiment, with a resin member indicated by an imaginary line.

FIG. 3 corresponds to the plan view of FIG. 2, with an electronic component and a plurality of bonding layers also indicated by imaginary lines.

FIG. 4 is a bottom view showing the electronic device according to the first embodiment.

FIG. 5 is a partially enlarged view showing a portion (near a first corner terminal) of FIG. 4.

FIG. 6 is a partially enlarged view showing a portion (near a second corner terminal) of FIG. 4.

FIG. 7 is a partially enlarged view showing a portion (near a third corner terminal) of FIG. 4.

FIG. 8 is a partially enlarged view showing a portion (near a fourth corner terminal) of FIG. 4.

FIG. 9 is a front view showing the electronic device according to the first embodiment.

FIG. 10 is a rear view showing the electronic device according to the first embodiment.

FIG. 11 is a right-side view showing the electronic device according to the first embodiment.

FIG. 12 is a left-side view showing the electronic device according to the first embodiment.

FIG. 13 is a cross-sectional view along line XIII-XIII in FIG. 3.

FIG. 14 is a cross-sectional view along line XIV-XIV in FIG. 3.

FIG. 15 is a cross-sectional view along line XV-XV in FIG. 3.

FIG. 16 is a cross-sectional view along line XVI-XVI in FIG. 3.

FIG. 17 is a cross-sectional view showing a step of a method for manufacturing the electronic device according to the first embodiment.

FIG. 18 is a cross-sectional view showing a step of the method for manufacturing the electronic device according to the first embodiment.

FIG. 19 is a cross-sectional view showing a step of the method for manufacturing the electronic device according to the first embodiment.

FIG. 20 is a cross-sectional view showing a step of the method for manufacturing the electronic device according to the first embodiment.

FIG. 21 is a cross-sectional view showing a step of the method for manufacturing the electronic device according to the first embodiment.

FIG. 22 is a cross-sectional view showing a step of the method for manufacturing the electronic device according to the first embodiment.

FIG. 23 is a cross-sectional view showing a step of the method for manufacturing the electronic device according to the first embodiment.

FIG. 24 is a bottom view of main parts, showing a step of the method for manufacturing the electronic device according to the first embodiment.

FIG. 25 is a cross-sectional view showing a step of the method for manufacturing the electronic device according to the first embodiment.

FIG. 26 is a bottom view of main parts, showing a step of the method for manufacturing the electronic device according to the first embodiment.

FIG. 27 is a cross-sectional view showing a step of the method for manufacturing the electronic device according to the first embodiment.

FIG. 28 is a bottom view showing an electronic device according to a first variation of the first embodiment.

FIG. 29 is a cross-sectional view showing the electronic device according to the first variation of the first embodiment, corresponding to the cross section shown in FIG. 15.

FIG. 30 is a cross-sectional view showing the electronic device according to the first variation of the first embodiment, corresponding to the cross section shown in FIG. 16.

FIG. 31 is a cross-sectional view showing an electronic device according to a second variation of the first embodiment, corresponding to the cross section shown in FIG. 13.

FIG. 32 is a cross-sectional view showing an electronic device according to a third variation of the first embodiment, corresponding to the cross section shown in FIG. 13.

FIG. 33 is a cross-sectional view showing the electronic device according to the third variation of the first embodiment, corresponding to the cross section shown in FIG. 15.

FIG. 34 is a plan view showing an electronic device according to a fourth variation of the first embodiment, with a resin member, an electronic component, and a plurality of bonding layers indicated by imaginary lines.

FIG. 35 is a partially enlarged view showing a portion (near a first corner terminal) of FIG. 34.

FIG. 36 is a cross-sectional view along line XXXVI-XXXVI in FIG. 35.

FIG. 37 is an enlarged view of main parts, showing another configuration of the electronic device according to the fourth variation of the first embodiment.

FIG. 38 is a bottom view showing an electronic device according to a fifth variation of the first embodiment.

FIG. 39 is a plan view showing an electronic device according to a second embodiment, with a resin member indicated by an imaginary line.

FIG. 40 corresponds to the plan view of FIG. 39, with an electronic component also indicated by an imaginary line.

FIG. 41 is a bottom view showing the electronic device according to the second embodiment.

FIG. 42 is a plan view showing an electronic device according to a third embodiment, with a resin member indicated by an imaginary line.

FIG. 43 corresponds to the plan view of FIG. 42, with an electronic component also indicated by an imaginary line.

FIG. 44 is a bottom view showing the electronic device according to the third embodiment.

### DETAILED DESCRIPTION OF EMBODIMENTS

The following describes preferred embodiments of an electronic device according to the present disclosure with reference to the drawings. In the following, the same or similar constituent elements are denoted by the same reference numerals, and the descriptions thereof are omitted. The terms such as “first”, “second” and “third” in the present disclosure are used merely as labels and are not necessarily intended to impose orders on the items to which these terms refer.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”.

### First Embodiment

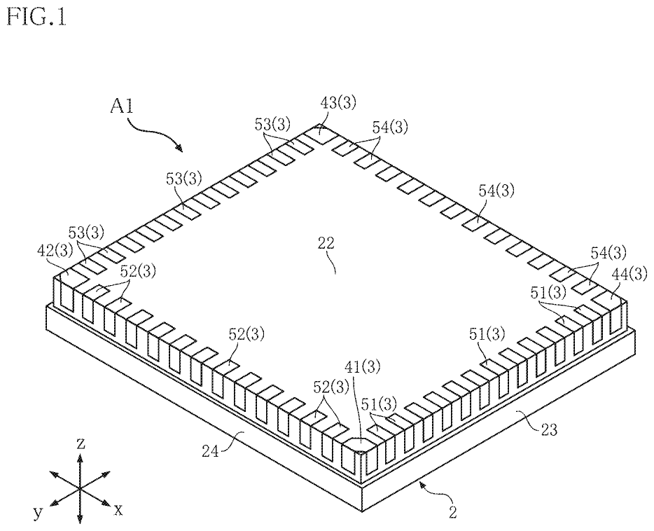

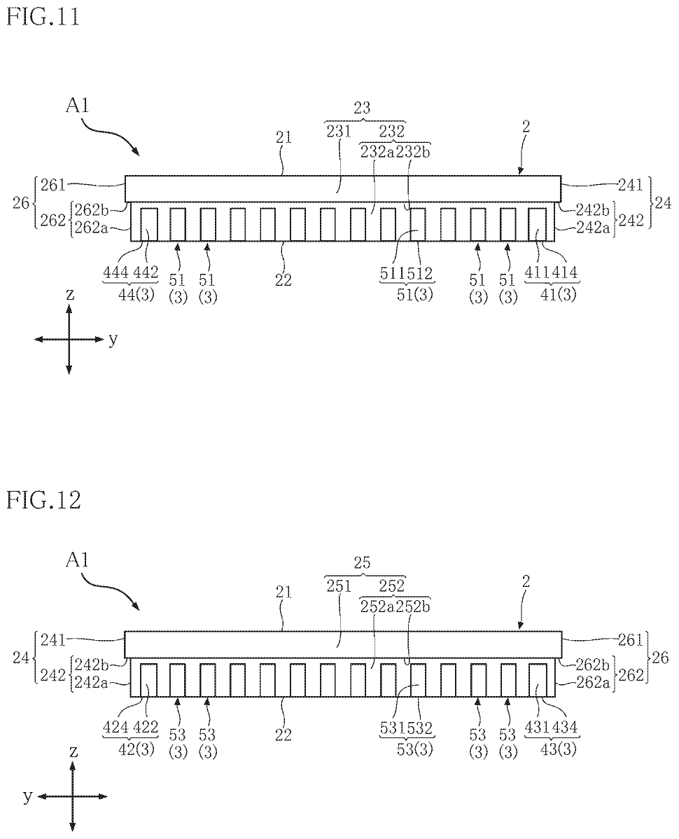

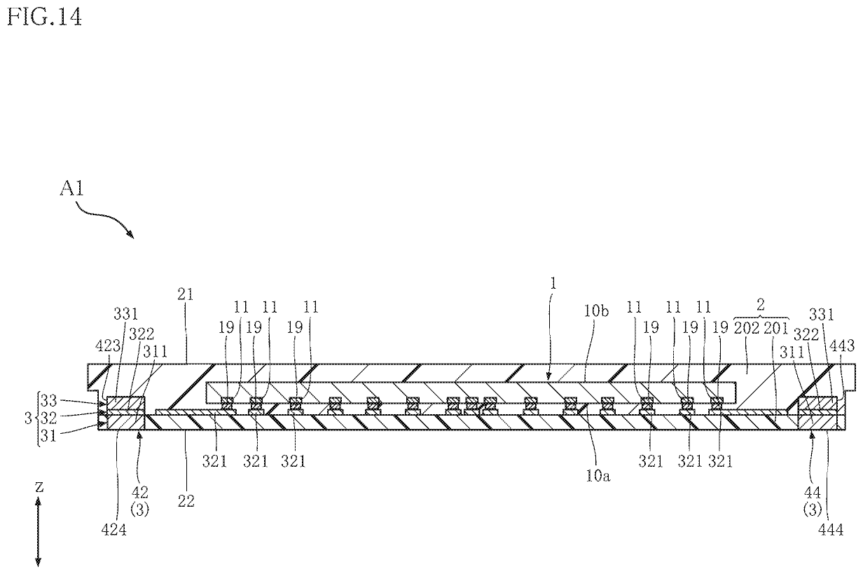

FIGS. 1 to 16 show an electronic device A1 according to a first embodiment. The electronic device A1 includes an electronic component 1, a resin member 2, and a conductive member 3.

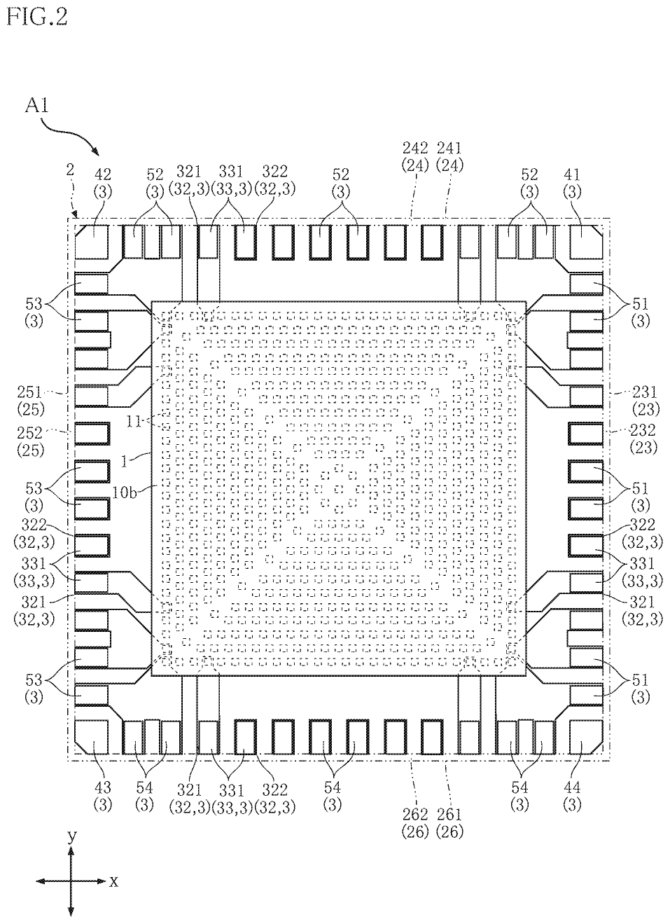

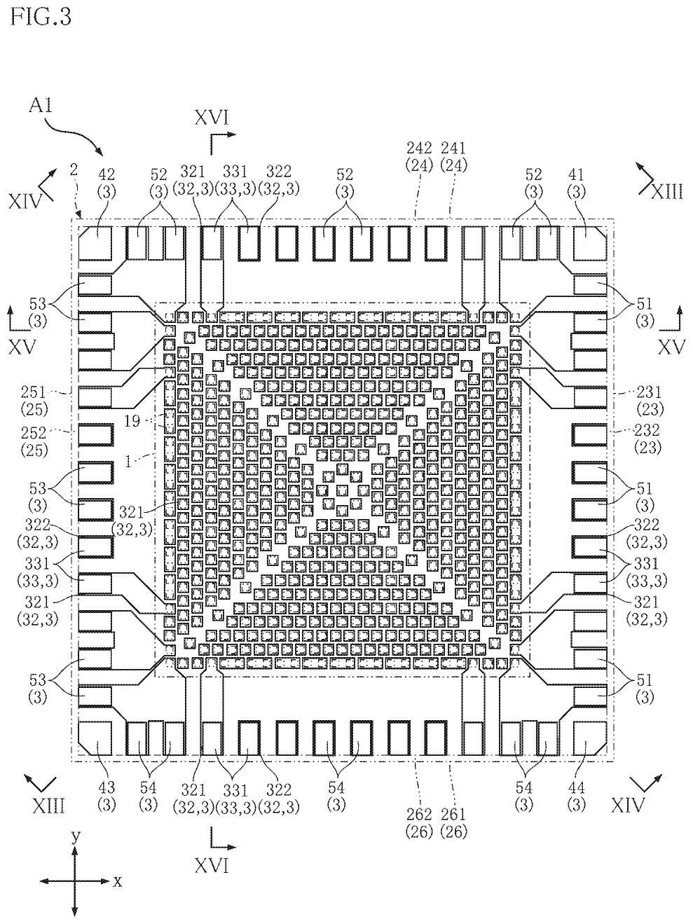

For convenience of explanation, the thickness direction of the electronic device A1 (resin member 2) is referred to as “thickness direction z”. In the present disclosure, the terms such as “top”, “bottom”, “upward”, “downward”, “upper surface”, and “lower surface” are used to indicate the relative positions of elements and components in the thickness direction z, and do not necessarily define the relationship with respect to the direction of gravity. Also, “plan view” refers to the view seen in the thickness direction z. A direction perpendicular to the thickness direction z is referred to as “first direction x” . The direction perpendicular to the thickness direction z and the first direction x is referred to as “second direction y”. For example, the first direction x is the horizontal direction in the plan views (see FIGS. 2 and 3) of the electronic device A1, and the second direction y is the vertical direction in the plan views (see FIGS. 2 and 3) of the electronic device A1.

The electronic device A1 is a surface-mounting package. As shown in FIG. 1, the package structure of the electronic device A1 may be a MAP-type QFN. As shown in FIGS. 2 to 4, the electronic device A1 has a rectangular shape in plan view, for example.

The electronic component 1 is an element that exerts an electrical function of the electronic device A1. The electronic component 1 has a rectangular shape in plan view, for example. The electronic component 1 be may a semiconductor element including a semiconductor material. In the present embodiment, an integrated circuit element is provided as an example of the semiconductor element. Alternatively, the electronic component 1 may be an active functional element (e.g., a transistor or a diode) or a passive functional element (e.g., a resistor, a capacitor, or an inductor) rather than an integrated circuit element.

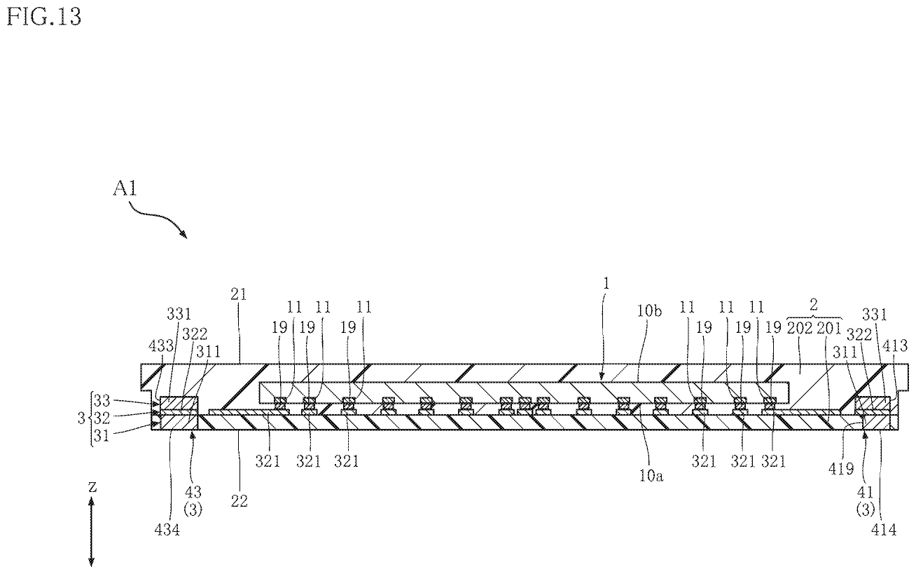

As shown in FIGS. 13 to 16, the electronic component 1 has an element obverse surface 10a and an element reverse surface 10b. The element obverse surface 10a and the element reverse surface 10b are spaced apart and face away from each other in the thickness direction z. The element obverse surface 10a faces downward in the thickness direction z, and the element reverse surface 10b faces upward in the thickness direction z. In the present embodiment, the electronic component 1 is flip-chip mounted onto the conductive member 3, with the element obverse surface 10a facing the conductive member 3 as shown in FIGS. 13 to 16.

As shown in FIGS. 13 to 16, the electronic component 1 has a plurality of electrodes 11 provided on the element obverse surface 10a. The number, arrangement, shape, and dimensions in plan view of the electrodes 11 are not limited to the illustrated examples, and may be changed suitably according to the electronic component 1 used. The electrodes 11 are bonded to the conductive member 3 via a plurality of bonding layers 19. Each bonding layer 19 may be a metal laminate formed by stacking a Sn layer on a Ni layer and then stacking a Ag layer on the Sn layer. Instead of the metal laminate, the bonding layer 19 may be a conductive bonding member such as solder, sintered metal, or metal paste material.

The resin member 2 is a sealer that protects the electronic component 1. The resin member 2 is made of an insulating resin material. The resin material is a black epoxy resin, for example. As shown in FIGS. 1 to 16, the resin member 2 covers the electronic component 1 and a portion of the conductive member 3. As shown in FIGS. 2 to 4, the resin member 2 has a rectangular shape in plan view. The resin member 2 has a resin obverse surface 21, a resin reverse surface 22, a first resin side surface 23, a second resin side surface 24, a third resin side surface 25, and a fourth resin side surface 26.

As shown in FIGS. 2 to 4, 9, 10, and 15, the first resin side surface 23 and the third resin side surface 25 are spaced apart from each other in the first direction x. The first resin side surface 23 and the third resin side surface 25 are connected to both of the resin obverse surface 21 and the resin reverse surface 22, and are flanked by these surfaces in the thickness direction z.

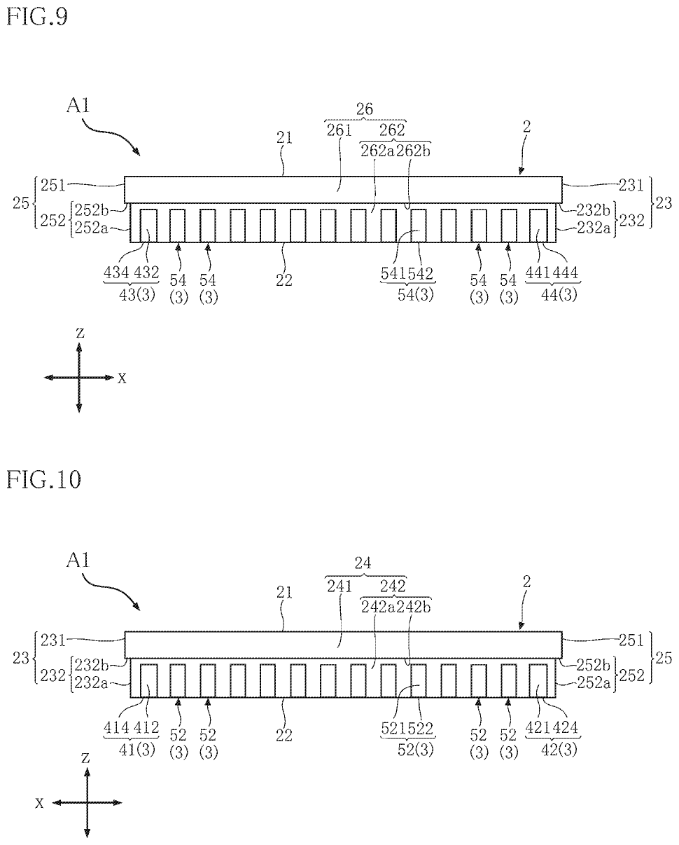

As shown in FIGS. 2 to 4, the first resin side surface 23 intersects with the second resin side surface 24 and the fourth resin side surface 26. In plan view, the first resin side surface 23 is positioned on a first side in the first direction x relative to the electronic component 1. As shown in FIGS. 9, 10, and 15, the first resin side surface 23 has a first side end surface 231 and a first resin recess 232.

As shown in FIGS. 9, 10, and 15, the first side end surface 231 faces the first side in the first direction x. The first side end surface 231 is flat. The first side end surface 231 forms a portion of the periphery of the resin member 2 in plan view.

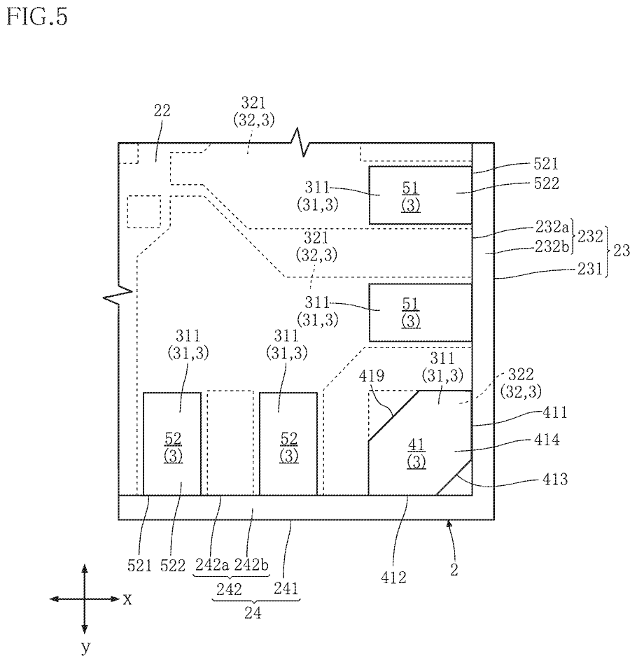

As shown in FIGS. 9, 10, and 15, the first resin recess 232 is recessed from the first side end surface 231 and connected to the resin reverse surface 22. The first resin recess 232 has a first wall surface 232a and a first bottom surface 232b. The first wall surface 232a faces in the same direction as the first side end surface 231. As shown in FIGS. 5, 8 to 10, and 15, the first wall surface 232a is offset toward a second side in the first direction x from the first side end surface 231. In other words, the first wall surface 232a is positioned inward of the electronic device A1 from the first side end surface 231 in plan view. The first bottom surface 232b is connected to the first side end surface 231 and the first wall surface 232a. In the example shown in FIGS. 9, 10, and 15, the first bottom surface 232b is flat and faces downward in the thickness direction z. Unlike this example, the first bottom surface 232b may be curved into a concave shape.

As shown in FIGS. 2 to 4, the third resin side surface 25 intersects with the second resin side surface 24 and the fourth resin side surface 26. The third resin side surface 25 is connected to an edge of the second resin side surface 24 and an edge of the fourth resin side surface 26, which are located opposite from the edges thereof connected to the first resin side surface 23 in the first direction x. In plan view, the third resin side surface 25 is positioned on the second side in the first direction x relative to the electronic component 1. As shown in FIGS. 9, 10, and 15, the third resin side surface 25 has a third side end surface 251 and a third resin recess 252.

As shown in FIGS. 9, 10, and 15, the third side end surface 251 faces the second side in the first direction x. The third side end surface 251 is flat. The third side end surface 251 forms a portion of the periphery of the resin member 2 in plan view.

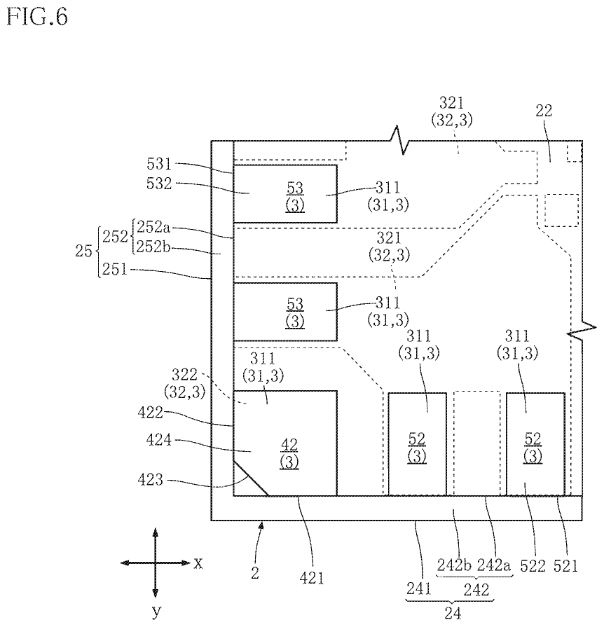

As shown in FIGS. 9, 10, and 15, the third resin recess 252 is recessed from the third side end surface 251 and connected to the resin reverse surface 22. The third resin recess 252 has a third wall surface 252a and a third bottom surface 252b. The third wall surface 252a faces in the same direction as the third side end surface 251. As shown in FIGS. 6, 7, 9, 10, and 15, the third wall surface 252a is offset toward the first side in the first direction x from the third side end surface 251. In other words, the third wall surface 252a is positioned inward of the electronic device A1 from the third side end surface 251 in plan view. The third bottom surface 252b is connected to the third side end surface 251 and the third wall surface 252a. In the example shown in FIGS. 9, 10, and 15, the third bottom surface 252b is flat and faces downward in the thickness direction z. Unlike this example, the third bottom surface 252b may be curved into a concave shape.

As shown in FIGS. 2 to 4, 11, 12, and 16, the second resin side surface 24 and the fourth resin side surface 26 are spaced apart from each other in the second direction y. The second resin side surface 24 and the fourth resin side surface 26 are connected to both of the resin obverse surface 21 and the resin reverse surface 22, and are flanked by these surfaces in the thickness direction z.

As shown in FIGS. 2 to 4, the second resin side surface 24 intersects with the first resin side surface 23 and the third resin side surface 25. In plan view, the second resin side surface 24 is positioned on a first side in the second direction y relative to the electronic component 1. As shown in FIGS. 11, 12, and 16, the second resin side surface 24 has a second side end surface 241 and a second resin recess 242.

As shown in FIGS. 11, 12, and 16, the second side end surface 241 faces the first side in the second direction y. The second side end surface 241 is flat. The second side end surface 241 forms a portion of the periphery of the resin member 2 in plan view.

As shown in FIGS. 11, 12, and 16, the second resin recess 242 is recessed from the second side end surface 241 and connected to the resin reverse surface 22. The second resin recess 242 has a second wall surface 242a and a second bottom surface 242b. The second wall surface 242a faces in the same direction as the second side end surface 241. As shown in FIGS. 5, 6, 11, 12, and 16, the second wall surface 242a is offset toward a second side in the second direction y from the second side end surface 241. In other words, the second wall surface 242a is positioned inward of the electronic device A1 from the second side end surface 241 in plan view. The second bottom surface 242b is connected to the second side end surface 241 and the second wall surface 242a. In the example shown in FIGS. 11, 12, and 16, the second bottom surface 242b is flat and faces downward in the thickness direction z. Unlike this example, the second bottom surface 242b may be curved into a concave shape.

As shown in FIGS. 2 to 4, the fourth resin side surface 26 intersects with the first resin side surface 23 and the third resin side surface 25. The fourth resin side surface 26 is connected to an edge of the first resin side surface 23 and an edge of the third resin side surface 25, which are located opposite from the edges thereof connected to the second resin side surface 24 in the second direction y. In plan view, the fourth resin side surface 26 is positioned on the second side in the second direction y relative to the electronic component 1. As shown in FIGS. 11, 12, and 16, the fourth resin side surface 26 has a fourth side end surface 261 and a fourth resin recess 262.

As shown in FIGS. 11, 12, and 16, the fourth side end surface 261 faces the second side in the second direction y. The fourth side end surface 261 is flat. The fourth side end surface 261 forms a portion of the periphery of the resin member 2 in plan view.

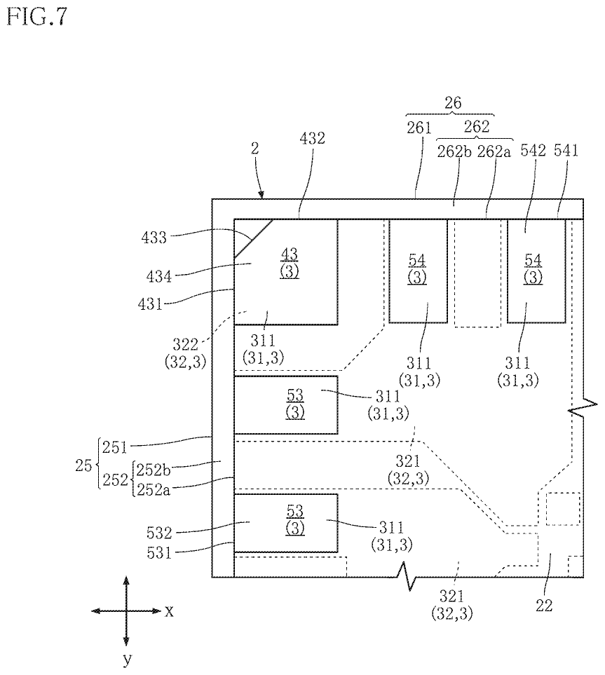

As shown in FIGS. 11, 12, and 16, the fourth resin recess 262 is recessed from the fourth side end surface 261 and connected to the resin reverse surface 22. The fourth resin recess 262 has a fourth wall surface 262a and a fourth bottom surface 262b. The fourth wall surface 262a faces in the same direction as the fourth side end surface 261. As shown in FIGS. 7, 8, 11, 12, and 16, the fourth wall surface 262a is offset toward the first side in the second direction y from the fourth side end surface 261. In other words, the fourth wall surface 262a is positioned inward of the electronic device A1 from the fourth side end surface 261 in plan view. The fourth bottom surface 262b is connected to the fourth side end surface 261 and the fourth wall surface 262a. In the example shown in FIGS. 11, 12, and 16, the fourth bottom surface 262b is flat and faces downward in the thickness direction z. Unlike this example, the fourth bottom surface 262b may be curved into a concave shape.

As shown in FIGS. 13 to 16, the resin member 2 includes a first resin portion 201 and a second resin portion 202. The first resin portion 201 and the second resin portion 202 are stacked in the thickness direction z, and are in contact with each other. For convenience of understanding, the resin member 2 is divided into the first resin portion 201 and the second resin portion 202. However, the present disclosure is not limited to the configuration where the boundary between the first resin portion 201 and the second resin portion 202 is visible, and also includes the configuration where the first resin portion 201 and the second resin portion 202 are integrated into a single resin portion. The first resin portion 201 is located below the second resin portion 202 in the thickness direction z. The lower surface (the surface facing downward in the thickness direction z) of the first resin portion 201 is the resin reverse surface 22. Accordingly, the first resin portion 201 has the resin reverse surface 22. The upper surface (the surface facing upward in the thickness direction z) of the second resin portion 202 is the resin obverse surface 21. Accordingly, the second resin portion 202 has the resin obverse surface 21. The upper surface (the surface facing upward in the thickness direction z) of the first resin portion 201 and the lower surface (the surface facing downward in the thickness direction z) of the second resin portion 202 are in contact with each other.

The conductive member 3 is electrically connected to the electronic component 1 as appropriate. As shown in FIGS. 2 to 8 and FIGS. 13 to 16, the conductive member 3 includes a first conductive layer 31, a second conductive layer 32, and a third conductive layer 33.

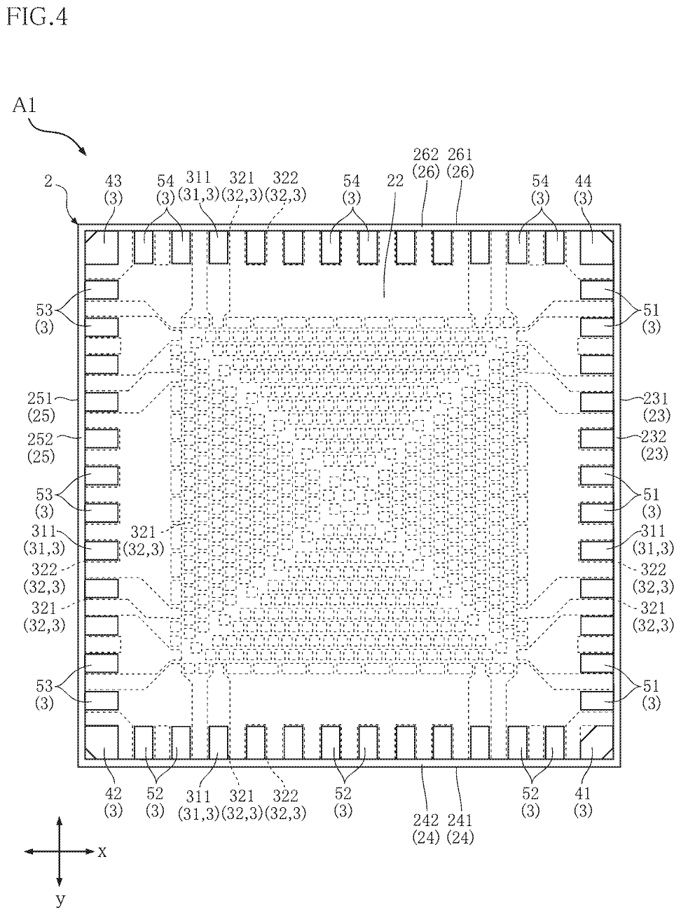

As shown in FIGS. 13 to 16, the first conductive layer 31 passes through the first resin portion 201 in the thickness direction z. Referring to FIGS. 13 to 16, the first conductive layer 31 is exposed from the resin reverse surface 22 and from one of the first resin side surface 23, the second resin side surface 24, the third resin side surface 25, and the fourth resin side surface 26. The first conductive layer 31 is made of copper or a copper alloy, for example. The first conductive layer 31 includes a plurality of columnar portions 311 spaced apart from each other. Each columnar portion 311 may have a prismatic shape, for example, and has a rectangular shape in plan view as shown in FIG. 4. In the present embodiment, each columnar portion 311 is partially exposed from the resin member 2.

As shown in FIGS. 13 to 16, the second conductive layer 32 is formed on the first conductive layer 31 or the first resin portion 201. The second conductive layer 32 is a pattern wiring. The second conductive layer 32 is made of copper or a copper alloy, for example. The second conductive layer 32 is electrically connected to the first conductive layer 31. As shown in FIG. 3, the second conductive layer 32 includes a plurality of wiring portions 321 and a plurality of intervening portions 322. Each wiring portion 321 is a portion of the second conductive layer 32, which is electrically connected to the electronic component 1. The bonding layers 19 are formed on the respective wiring portions 321. Each intervening portion 322 is a portion of the second conductive layer 32, which is not electrically connected to the electronic component 1. The intervening portions 322 are arranged between the first conductive layer 31 and the third conductive layer 33 in the thickness direction z.

As shown in FIGS. 13 to 16, the third conductive layer 33 is formed on the second conductive layer 32. The third conductive layer 33 is partially covered with the second resin portion 202. The third conductive layer 33 is exposed from one of the first resin side surface 23, the second resin side surface 24, the third resin side surface 25, and the fourth resin side surface 26. The third conductive layer 33 is made of copper or a copper alloy, for example. The third conductive layer 33 includes a plurality of columnar portions 331 spaced apart from each other. Each columnar portion 331 may have a prismatic shape, for example, and has a rectangular shape in plan view as shown in FIG. 3. In the present embodiment, each columnar portion 331 is partially exposed from the resin member 2. As can be understood from FIGS. 2 to 4, each columnar portion 331 overlaps with one of the columnar portions 311 in plan view.

As shown in FIGS. 1 to 16, the conductive member 3 includes a first corner terminal 41, a second corner terminal 42, a third corner terminal 43, a fourth corner terminal 44, a plurality of first side terminals 51, a plurality of second side terminals 52, a plurality of third side terminals 53, and a plurality of fourth side terminals 54. The first corner terminal 41, the second corner terminal 42, the third corner terminal 43, the fourth corner terminal 44, the first side terminals 51, the second side terminals 52, the third side terminals 53, and the fourth side terminals 54 are partially exposed from the resin member 2. Some of the first corner terminal 41, the second corner terminal 42, the third corner terminal 43, the fourth corner terminal 44, the first side terminals 51, the second side terminals 52, the third side terminals 53, and the fourth side terminals 54 are electrically connected to the electronic component 1. The first corner terminal 41, the second corner terminal 42, the third corner terminal 43, the fourth corner terminal 44, the first side terminals 51, the second side terminals 52, the third side terminals 53, and the fourth side terminals 54 are used when the electronic device A1 is mounted on the circuit board of an electronic device or the like.

As shown in FIGS. 2 to 4, the first corner terminal 41, the second corner terminal 42, the third corner terminal 43, and the fourth corner terminal 44 are arranged near the four corners of the resin member 2 in plan view. In the present embodiment, none of the first corner terminal 41, the second corner terminal 42, the third corner terminal 43, and the fourth corner terminal 44 is electrically connected to the electronic component 1.

As shown in FIGS. 5, 10, and 11, the first corner terminal 41 is exposed from the resin reverse surface 22, the first resin side surface 23, and the second resin side surface 24. The first corner terminal 41 includes a columnar portion 311 of the first conductive layer 31, an intervening portion 322 of the second conductive layer 32, and a columnar portion 331 of the third conductive layer 33. The columnar portion 311 in the first corner terminal 41 is an example of a “first columnar portion”, and the columnar portion 331 in the first corner terminal 41 is an example of a “second columnar portion”. As shown in FIG. 5, the first corner terminal 41 has a first exposed surface 411, a second exposed surface 412, a first surface 413, and a reverse surface 414.

The first exposed surface 411 is exposed from the first resin side surface 23. In the example shown in FIG. 5, the first exposed surface 411 is exposed from the first resin recess 232 of the first resin side surface 23. The first exposed surface 411 faces the first side in the first direction x. The first exposed surface 411 is flat. The first exposed surface 411 is flush with the first wall surface 232a of the first resin recess 232. In the present disclosure, the term “flush” refers to, unless otherwise specified, not only the situation where two or more surfaces form an ideal smooth surface, but also the situation where two or more surfaces inevitably form a surface with irregularities during a step (e.g., a grinding step and a dicing step described below) in the manufacturing process of the electronic device A1, and the situation where a processing mark is formed over two or more surfaces.

The second exposed surface 412 is exposed from the second resin side surface 24. In the example shown in FIG. 5, the second exposed surface 412 is exposed from the second resin recess 242 of the second resin side surface 24. The second exposed surface 412 faces the first side in the second direction y. The second exposed surface 412 is flat. The second exposed surface 412 is flush with the second wall surface 242a of the second resin recess 242.

The first surface 413 is connected to the first exposed surface 411 and the second exposed surface 412 in plan view. The first surface 413 is covered with the resin member 2. In the example shown in FIG. 5, the first surface 413 is flat and inclined relative to the first exposed surface 411 and the second exposed surface 412. Alternatively, the first surface 413 may be curved into a recess or a protrusion in plan view.

The reverse surface 414 faces downward in the thickness direction z. As shown in FIG. 5, the reverse surface 414 is exposed from the resin reverse surface 22. The reverse surface 414 is flat. The reverse surface 414 is flush with the resin reverse surface 22.

As shown in FIG. 5, the first corner terminal 41 further has a covered surface 419. The covered surface 419 is formed on the opposite side from the first surface 413. The covered surface 419 is covered with the resin member 2. The covered surface 419 is flat. For example, the covered surface 419 is formed on the columnar portion 311 of the first corner terminal 41, but not on the intervening portion 322 and columnar portion 331 of the first corner terminal 41. Alternatively, the covered surface 419 may be formed from the columnar portion 311 to the intervening portion 322 of the first corner terminal 41 or further to the columnar portion 331. The covered surface 419 is formed on the first corner terminal 41 as a mark indicating the orientation of the electronic device A1. Note that the covered surface 419 may be formed on any one of the second corner terminal 42, the third corner terminal 43, the fourth corner terminal 44, the first side terminals 51, the second side terminals 52, the third side terminals 53, and the fourth side terminals 54, instead of the first corner terminal 41.

As shown in FIGS. 6, 10, and 12, the second corner terminal 42 is exposed from the resin reverse surface 22, the second resin side surface 24, and the third resin side surface 25. The second corner terminal 42 includes a columnar portion 311 of the first conductive layer 31, an intervening portion 322 of the second conductive layer 32, and a columnar portion 331 of the third conductive layer 33. As shown in FIG. 6, the second corner terminal 42 has a third exposed surface 421, a fourth exposed surface 422, a second surface 423, and a reverse surface 424.

The third exposed surface 421 is exposed from the second resin side surface 24. In the example shown in FIG. 6, the third exposed surface 421 is exposed from the second resin recess 242 of the second resin side surface 24. The third exposed surface 421 faces the first side in the second direction y. The third exposed surface 421 is flat. The third exposed surface 421 is flush with the second wall surface 242a of the second resin recess 242.

The fourth exposed surface 422 is exposed from the third resin side surface 25. In the example shown in FIG. 6, the fourth exposed surface 422 is exposed from the third resin recess 252 of the third resin side surface 25. The fourth exposed surface 422 faces the second side in the first direction x. The fourth exposed surface 422 is flat. The fourth exposed surface 422 is flush with the third wall surface 252a of the third resin recess 252.

The second surface 423 is connected to the third exposed surface 421 and the fourth exposed surface 422 in plan view. The second surface 423 is covered with the resin member 2. In the example shown in FIG. 6, the second surface 423 is flat and inclined relative to the third exposed surface 421 and the fourth exposed surface 422. Alternatively, the second surface 423 may be curved into a recess or a protrusion in plan view.

The reverse surface 424 faces downward in the thickness direction z. As shown in FIG. 6, the reverse surface 424 is exposed from the resin reverse surface 22. The reverse surface 424 is flat. The reverse surface 424 is flush with the resin reverse surface 22.

As shown in FIGS. 7, 9, and 12, the third corner terminal 43 is exposed from the resin reverse surface 22, the third resin side surface 25, and the fourth resin side surface 26. The third corner terminal 43 includes a columnar portion 311 of the first conductive layer 31, an intervening portion 322 of the second conductive layer 32, and a columnar portion 331 of the third conductive layer 33. As shown in FIG. 7, the third corner terminal 43 has a fifth exposed surface 431, a sixth exposed surface 432, a third surface 433, and a reverse surface 434.

The fifth exposed surface 431 is exposed from the third resin side surface 25. In the example shown in FIG. 7, the fifth exposed surface 431 is exposed from the third resin recess 252 of the third resin side surface 25. The fifth exposed surface 431 faces the second side in the first direction x. The fifth exposed surface 431 is flat. The fifth exposed surface 431 is flush with the third wall surface 252a of the third resin recess 252.

The sixth exposed surface 432 is exposed from the fourth resin side surface 26. In the example shown in FIG. 7, the sixth exposed surface 432 is exposed from the fourth resin recess 262 of the fourth resin side surface 26. The sixth exposed surface 432 faces the second side in the second direction y. The sixth exposed surface 432 is flat. The sixth exposed surface 432 is flush with the fourth wall surface 262a of the fourth resin recess 262.

The third surface 433 is connected to the fifth exposed surface 431 and the sixth exposed surface 432 in plan view. The third surface 433 is covered with the resin member 2. In the example shown in FIG. 7, the third surface 433 is flat and inclined relative to the fifth exposed surface 431 and the sixth exposed surface 432. Alternatively, the third surface 433 may be curved into a recess or a protrusion in plan view.

The reverse surface 434 faces downward in the thickness direction z. As shown in FIG. 7, the reverse surface 434 is exposed from the resin reverse surface 22. The reverse surface 434 is flat. The reverse surface 434 is flush with the resin reverse surface 22.

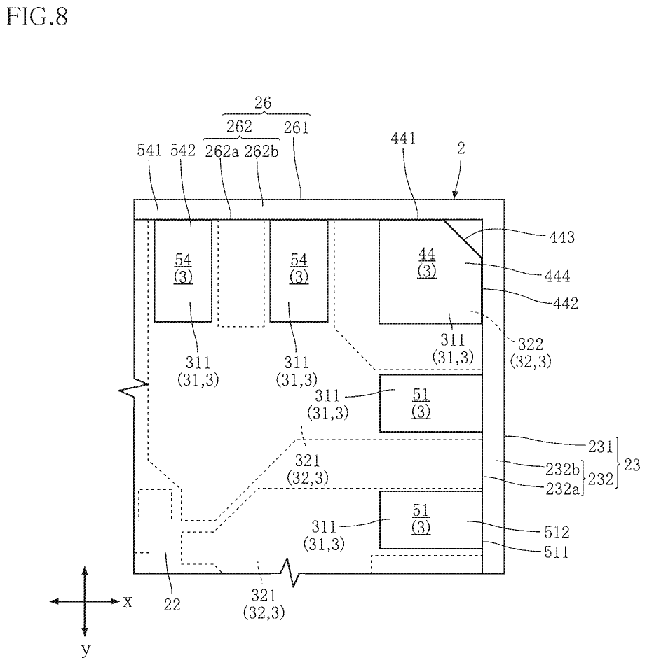

As shown in FIGS. 8, 9, and 11, the fourth corner terminal 44 is exposed from the resin reverse surface 22, the fourth resin side surface 26, and the first resin side surface 23. The fourth corner terminal 44 includes a columnar portion 311 of the first conductive layer 31, an intervening portion 322 of the second conductive layer 32, and a columnar portion 331 of the third conductive layer 33. As shown in FIG. 8, the fourth corner terminal 44 has a seventh exposed surface 441, an eighth exposed surface 442, a fourth surface 443, and a reverse surface 444.

The seventh exposed surface 441 is exposed from the fourth resin side surface 26. In the example shown in FIG. 8, the seventh exposed surface 441 is exposed from the fourth resin recess 262 of the fourth resin side surface 26. The seventh exposed surface 441 faces the second side in the second direction y. The seventh exposed surface 441 is flat. The seventh exposed surface 441 is flush with the fourth wall surface 262a of the fourth resin recess 262.

The eighth exposed surface 442 is exposed from the first resin side surface 23. In the example shown in FIG. 8, the eighth exposed surface 442 is exposed from the first resin recess 232 of the first resin side surface 23. The eighth exposed surface 442 faces the first side in the first direction x. The eighth exposed surface 442 is flat. The eighth exposed surface 442 is flush with the first wall surface 232a of the first resin recess 232.

The fourth surface 443 is connected to the seventh exposed surface 441 and the eighth exposed surface 442 in plan view. The fourth surface 443 is covered with the resin member 2. In the example shown in FIG. 8, the fourth surface 443 is flat and inclined relative to the seventh exposed surface 441 and the eighth exposed surface 442. Alternatively, the fourth surface 443 may be curved into a recess or a protrusion in plan view.

The reverse surface 444 faces downward in the thickness direction z. As shown in FIG. 8, the reverse surface 444 is exposed from the resin reverse surface 22. The reverse surface 444 is flat. The reverse surface 444 is flush with the resin reverse surface 22.

The first exposed surface 411, second exposed surface 412, and reverse surface 414 of the first corner terminal 41, the third exposed surface 421, fourth exposed surface 422, and reverse surface 424 of the second corner terminal 42, the fifth exposed surface 431, sixth exposed surface 432, and reverse surface 434 of the third corner terminal 43, and the seventh exposed surface 441, eighth exposed surface 442, and reverse surface 444 of the fourth corner terminal 44 are each covered with a non-illustrated plating layer. The plating layer is formed to improve the wettability of solder. The solder is used, for example, when the electronic device A1 is mounted on the circuit board of an electronic device or the like. The plating layer includes a Ni layer, a Pd layer, and a Au layer formed by electroless plating described below, for example. The constituent materials of the plating layer are not limited to these.

As shown in FIGS. 3 and 4, the first side terminals 51 are arranged along the first resin side surface 23. Thus, the first side terminals 51 are aligned in the second direction y. The first side terminals 51 are arranged between the first corner terminal 41 and the fourth corner terminal 44 in the second direction y. Each of the first side terminals 51 is exposed from the resin reverse surface 22 and the first resin side surface 23. The first side terminals 51 include those electrically connected to the electronic component 1 and those not electrically connected to the electronic component 1. Each of the first side terminals 51 electrically connected to the electronic component 1 includes a columnar portion 311, a wiring portion 321, and a columnar portion 331. Each of the first side terminals 51 not electrically connected to the electronic component 1 includes a columnar portion 311, an intervening portion 322, and a columnar portion 331.

As shown in FIGS. 5 and 8, each of the first side terminals 51 includes an exposed surface 511 and a reverse surface 512. The surfaces of each first side terminal 51 are covered with the resin member 2 except for the exposed surface 511 and the reverse surface 512.

The exposed surface 511 of each first side terminal 51 is exposed from the first resin side surface 23. In the example shown in FIGS. 5 and 8, the exposed surface 511 is exposed from the first resin recess 232 of the first resin side surface 23. The exposed surface 511 is flat. The exposed surface 511 is flush with the first wall surface 232a of the first resin recess 232.

As shown in FIGS. 5 and 8, the reverse surface 512 of each first side terminal 51 is exposed from the resin reverse surface 22. The reverse surface 512 is flush with the resin reverse surface 22. The reverse surface 512 is connected to the exposed surface 511.

As shown in FIGS. 3 and 4, the second side terminals 52 are arranged along the second resin side surface 24. Thus, the second side terminals 52 are aligned in the first direction x. The second side terminals 52 are arranged between the first corner terminal 41 and the second corner terminal 42 in the first direction x. Each of the second side terminals 52 is exposed from the resin reverse surface 22 and the second resin side surface 24. The second side terminals 52 include those electrically connected to the electronic component 1 and those not electrically connected to the electronic component 1. Each of the second side terminals 52 electrically connected to the electronic component 1 includes a columnar portion 311, a wiring portion 321, and a columnar portion 331. Each of the second side terminals 52 not electrically connected to the electronic component 1 includes a columnar portion 311, an intervening portion 322, and a columnar portion 331.

As shown in FIGS. 5 and 6, each of the second side terminals 52 includes an exposed surface 521 and a reverse surface 522. The surfaces of each second side terminal 52 are covered with the resin member 2 except for the exposed surface 521 and the reverse surface 522.

The exposed surface 521 of each second side terminal 52 is exposed from the second resin side surface 24. In the example shown in FIGS. 5 and 6, the exposed surface 521 is exposed from the second resin recess 242 of the second resin side surface 24. The exposed surface 521 is flat. The exposed surface 521 is flush with the second wall surface 242a of the second resin recess 242.

As shown in FIGS. 5 and 6, the reverse surface 522 of each second side terminal 52 is exposed from the resin reverse surface 22. The reverse surface 522 is flush with the resin reverse surface 22. The reverse surface 522 is connected to the exposed surface 521.

As shown in FIGS. 3 and 4, the third side terminals 53 are arranged along the third resin side surface 25. Thus, the third side terminals 53 are aligned in the second direction y. The third side terminals 53 are arranged between the second corner terminal 42 and the third corner terminal 43 in the second direction y. Each of the third side terminals 53 is exposed from the resin reverse surface 22 and the third resin side surface 25. The third side terminals 53 include those electrically connected to the electronic component 1 and those not electrically connected to the electronic component 1. Each of the third side terminals 53 electrically connected to the electronic component 1 includes a columnar portion 311, a wiring portion 321, and a columnar portion 331. Each of the third side terminals 53 not electrically connected to the electronic component 1 includes a columnar portion 311, an intervening portion 322, and a columnar portion 331.

As shown in FIGS. 6 and 7, each of the third side terminals 53 includes an exposed surface 531 and a reverse surface 532. The surfaces of each third side terminal 53 are covered with the resin member 2 except for the exposed surface 531 and the reverse surface 532.

The exposed surface 531 of each third side terminal 53 is exposed from the third resin side surface 25. In the example shown in FIGS. 6 and 7, the exposed surface 531 is exposed from the third resin recess 252 of the third resin side surface 25. The exposed surface 531 is flat. The exposed surface 531 is flush with the third wall surface 252a of the third resin recess 252.

As shown in FIGS. 6 and 7, the reverse surface 532 of each third side terminal 53 is exposed from the resin reverse surface 22. The reverse surface 532 is flush with the resin reverse surface 22. The reverse surface 532 is connected to the exposed surface 531.

As shown in FIGS. 3 and 4, the fourth side terminals 54 are arranged along the fourth resin side surface 26. Thus, the fourth side terminals 54 are aligned in the first direction x. The fourth side terminals 54 are arranged between the third corner terminal 43 and the fourth corner terminal 44 in the first direction x. Each of the fourth side terminals 54 is exposed from the resin reverse surface 22 and the fourth resin side surface 26. The fourth side terminals 54 include those electrically connected to the electronic component 1 and those not electrically connected to the electronic component 1. Each of the fourth side terminals 54 electrically connected to the electronic component 1 includes a columnar portion 311, a wiring portion 321, and a columnar portion 331. Each of the fourth side terminals 54 not electrically connected to the electronic component 1 includes a columnar portion 311, an intervening portion 322, and a columnar portion 331.

As shown in FIGS. 7 and 8, each of the fourth side terminals 54 includes an exposed surface 541 and a reverse surface 542. The surfaces of each fourth side terminal 54 are covered with the resin member 2 except for the exposed surface 541 and the reverse surface 542.

The exposed surface 541 of each fourth side terminal 54 is exposed from the fourth resin side surface 26. In the example shown in FIGS. 7 and 8, the exposed surface 541 is exposed from the fourth resin recess 262 of the fourth resin side surface 26. The exposed surface 541 is flat. The exposed surface 541 is flush with the fourth wall surface 262a of the fourth resin recess 262.

As shown in FIGS. 7 and 8, the reverse surface 542 of each fourth side terminal 54 is exposed from the resin reverse surface 22. The reverse surface 542 is flush with the resin reverse surface 22. The reverse surface 542 is connected to the exposed surface 541.

The exposed surface 511 and reverse surface 512 of each first side terminal 51, the exposed surface 521 and reverse surface 522 of each second side terminal 52, the exposed surface 531 and reverse surface 532 of each third side terminal 53, and the exposed surface 541 and reverse surface 542 of each fourth side terminal 54 are each covered with a non-illustrated plating layer. The plating layer is formed to improve the wettability of solder. The solder is used, for example, when the electronic device A1 is mounted on the circuit board of an electronic device or the like. The plating layer includes a Ni layer, a Pd layer, and a Au layer formed by electroless plating described below, for example. The constituent materials of the plating layer are not limited to these.

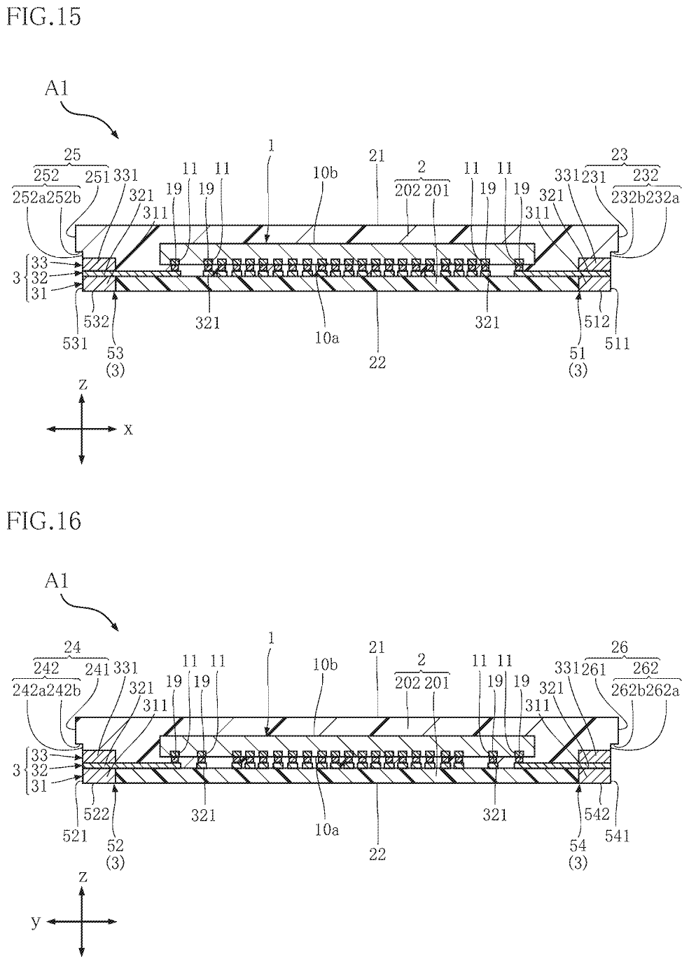

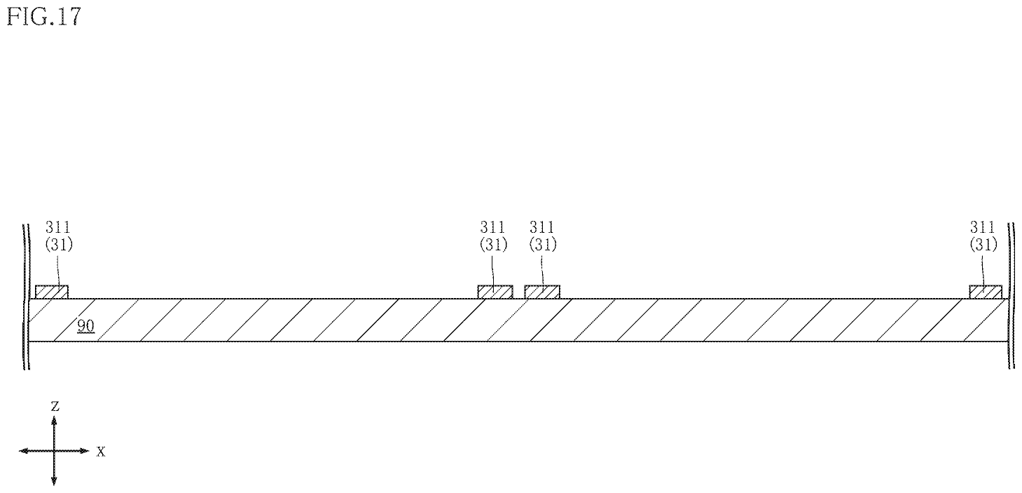

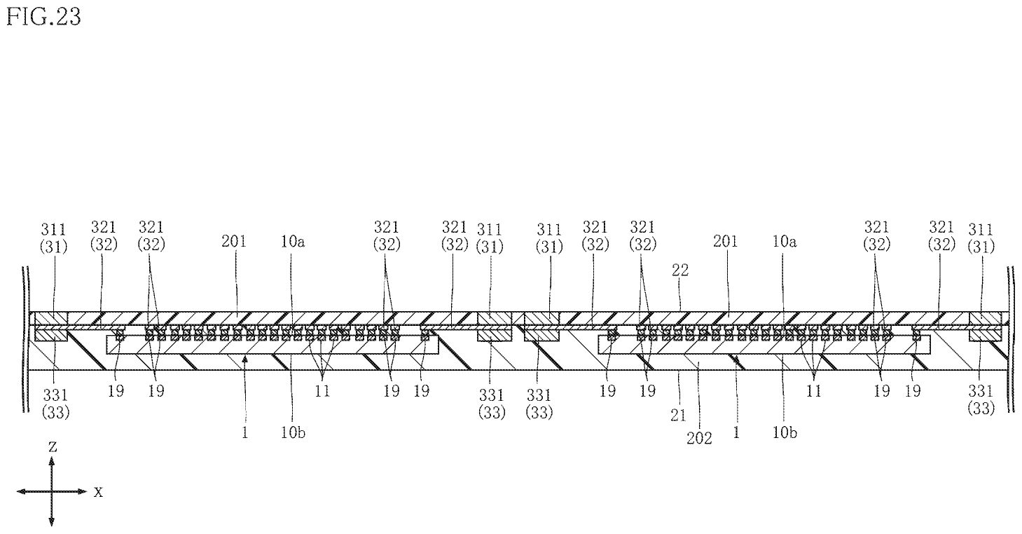

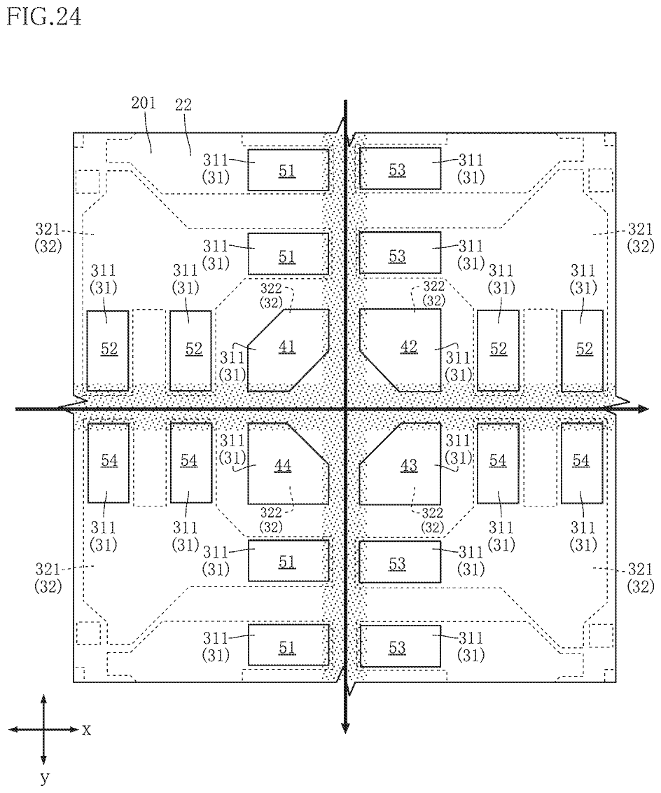

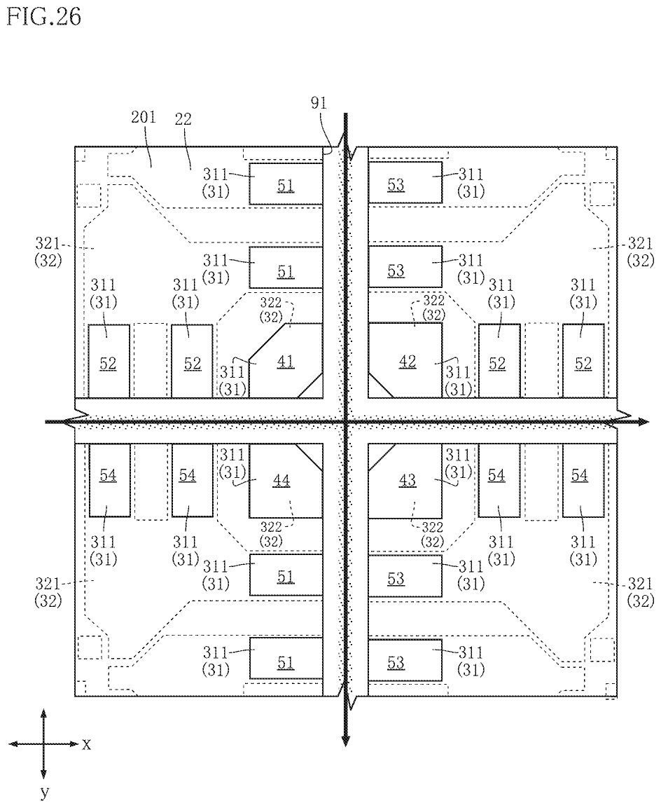

Next, a method for manufacturing the electronic device A1 will be described with reference to FIGS. 17 to 27. FIGS. 17 to 23, 25, and 27 are cross-sectional views each showing a step of the method for manufacturing the electronic device A1, and correspond to the cross section of the electronic device A1 in FIG. 15. FIGS. 24 and 26 are enlarged plan views of main parts, each showing a step of the method for manufacturing the electronic device A1. As will be understood from the process described in detail below, each of the intermediate products of the electronic device A1 during the manufacturing steps shown in FIGS. 23 to 27 is arranged with its bottom surface facing upward in the thickness direction Z.

First, as shown in FIG. 17, a support substrate 90 is prepared, and the first conductive layer 31 is formed on the support substrate 90. The support substrate 90 may be a silicon substrate, for example. The support substrate 90 may be a glass substrate instead of a silicon substrate. The support substrate 90 to be prepared is large enough to arrange a plurality of electronic devices A1 in a matrix, i.e., in the vertical and horizontal directions, in plan view. In the formation of the first conductive layer 31, a metal film made of copper or a copper alloy is formed by sputtering, for example. Then, a resist layer is patterned on the metal film by photolithography, and a plurality of metal columns made of copper or a copper alloy are formed by electrolytic plating on a portion of the metal film exposed from the resist film. Next, the resist layer is removed, and then, a portion of the metal film exposed from the metal columns is removed. As a result, the first conductive layer 31 including a plurality of columnar portions 311 is formed.

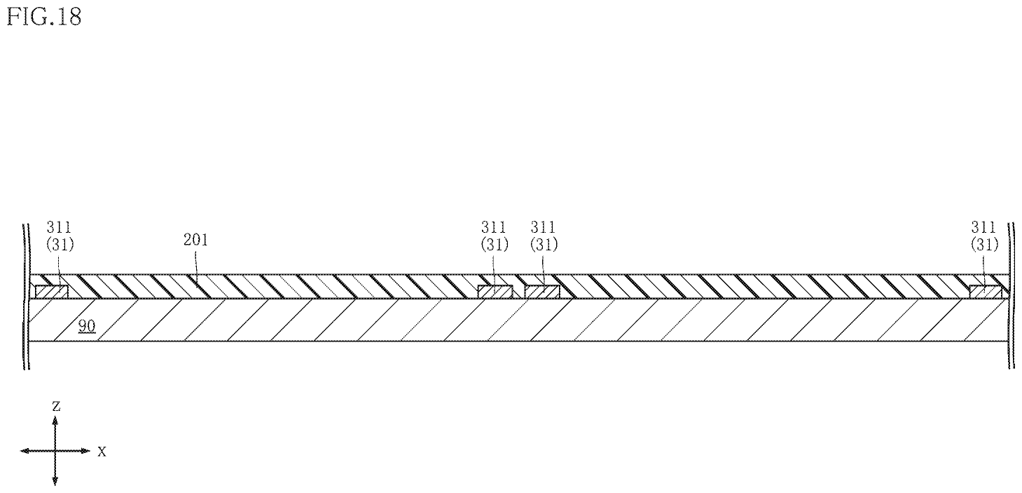

Next, as shown in FIG. 18, the first resin portion 201 is formed to cover the first conductive layer 31 formed on the support substrate 90. The first resin portion 201 is an electrically insulating resin, and is made of an epoxy resin or polyimide, for example. The first resin portion 201 is formed by molding, for example.

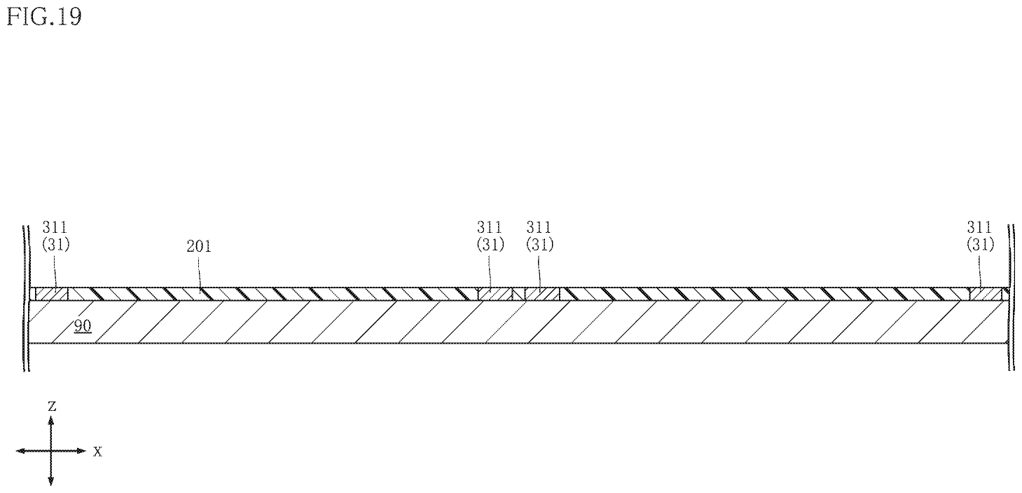

Next, as shown in FIG. 19, the first resin portion 201 is ground from its upper surface to expose the top surface of the first conductive layer 31. The upper surface of the ground first resin portion 201 will be the boundary with the second resin portion 202 that is to be formed later. The grinding is performed with a grinding stone, for example.

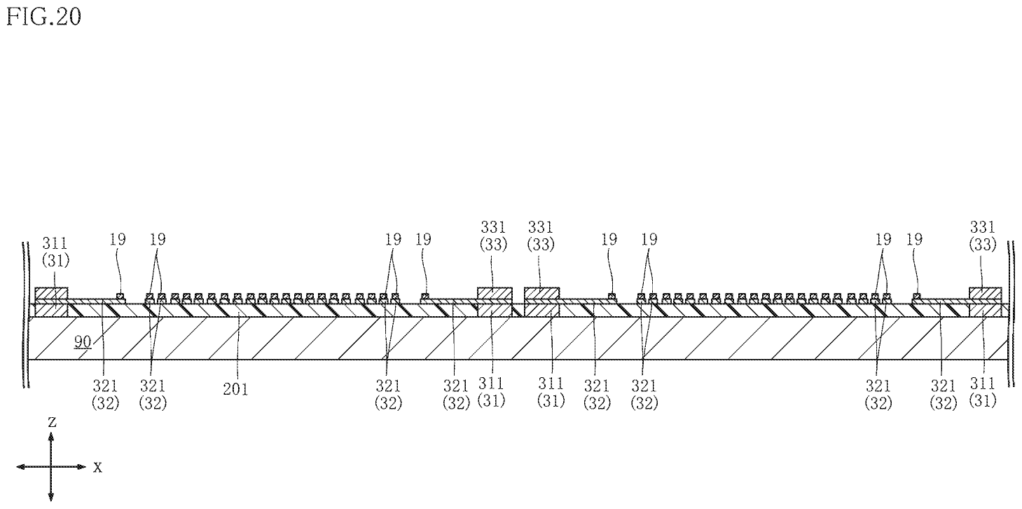

Next, as shown in FIG. 20, the second conductive layer 32, the bonding layers 19, and the third conductive layer 33 are formed on the upper surface of the first resin portion 201. The step of forming the second conductive layer 32, the bonding layers 19, and the third conductive layer 33 includes the following five processes (first to fifth processes).

In a first process, a seed layer is uniformly formed on the upper surface of the first resin portion 201. The seed layer may be a metallic thin film formed by sputtering, for example. The metallic thin film is made of nickel or chromium, for example.

In a second process, a patterned resist layer is formed by photolithography on the seed layer formed in the first process, and copper or a copper alloy is deposited by electrolytic plating on a portion of the seed layer exposed from the resist layer. This forms the second conductive layer 32 unified by the seed layer.

In a third process, a patterned resist layer is formed by photolithography on the second conductive layer 32 formed in the second process, and a Ni layer, a Sn layer, and a Ag layer are stacked in sequence by electrolytic plating on a portion of the second conductive layer 32 exposed from the resist layer. Then, the resist layer is removed. As a result, the bonding layers 19 are formed.

In a fourth process, a patterned resist layer is formed by photolithography on the second conductive layer 32 formed in the second process, and a plurality of metal columns made of copper or a copper alloy are formed by electrolytic plating on a portion of the second conductive layer 32 exposed from the resist layer. Then, the resist layer is removed. As a result, the third conductive layer 33 including the plurality of columnar portions 331 is formed.

In a fifth process, portions of the seed layer formed in the first process, which are exposed from the second conductive layer 32, the bonding layers 19, and the third conductive layer 33, are removed. As a result, the second conductive layer 32 divided into the wiring portions 321 and the intervening portions 322 are formed from the second conductive layer 32 unified by the seed layer.

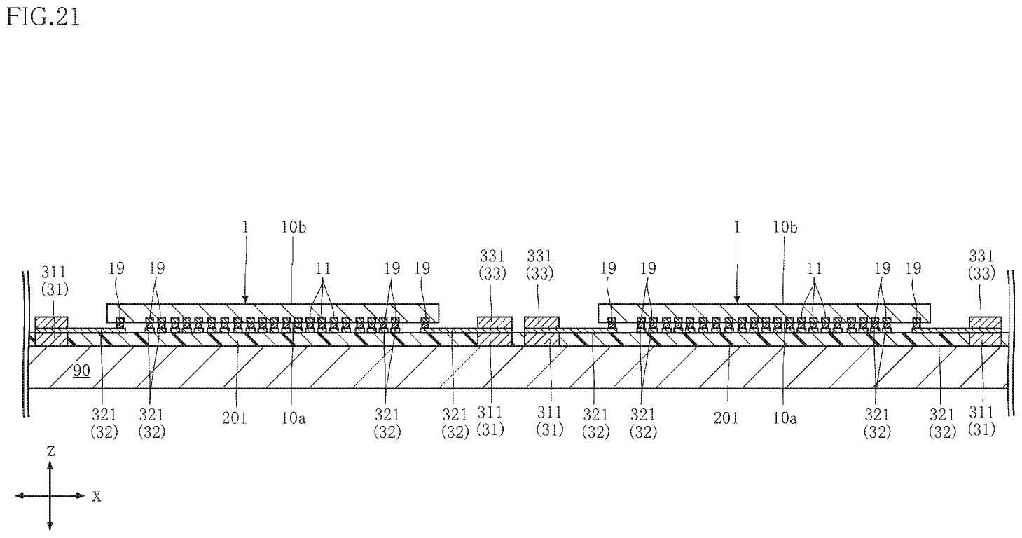

Next, as shown in FIG. 21, the electronic component 1 is mounted on the second conductive layer 32 via the bonding layers 19. At this point, the electrodes 11 arranged on the element obverse surface 10a are bonded to the second conductive layer 32 via the bonding layers 19, and the electronic component 1 is mounted in the state where the element obverse surface 10a faces the second conductive layer 32. In other words, the electronic component 1 is flip-chip mounted to the support substrate 90 via the first resin portion 201, the second conductive layer 32, the bonding layers 19, and so on.

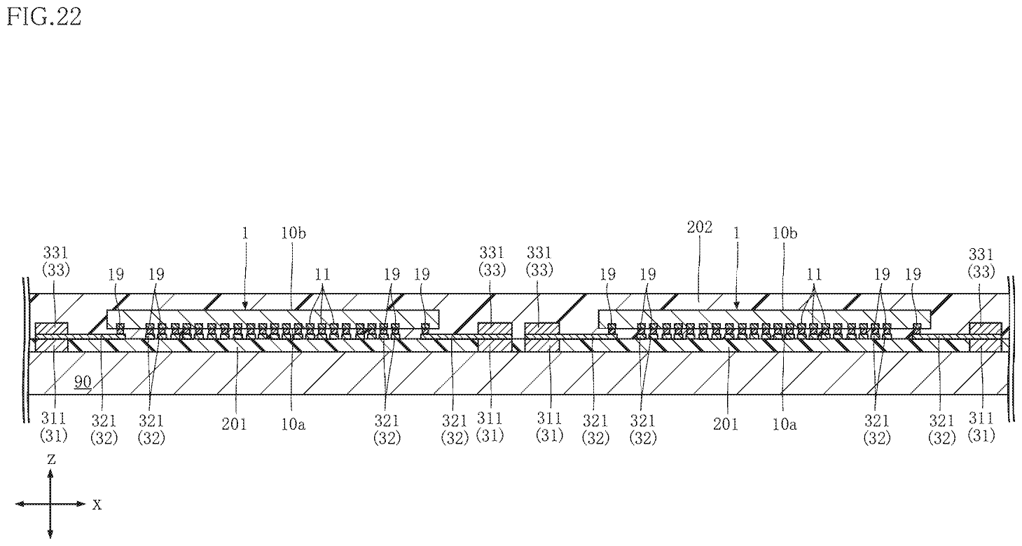

Next, as shown in FIG. 22, the second resin portion 202 is formed to cover the first resin portion 201, the second conductive layer 32, the third conductive layer 33, the bonding layers 19, and the electronic component 1. As with the first resin portion 201, the second resin portion 202 is an electrically insulating resin, and is made of an epoxy resin or polyimide, for example. The second resin portion 202 is formed by molding, for example.

Next, as shown in FIG. 23, the intermediate product is turned upside down so that the support substrate 90 is positioned upward, and the support substrate 90 is ground toward the second resin portion 202 located at the bottom to remove the support substrate 90. At this point, the grinding is performed until the first resin portion 201 reaches a predetermined thickness. As a result of the grinding, the bottom surface of each columnar portion 311 is exposed from the first resin portion 201.

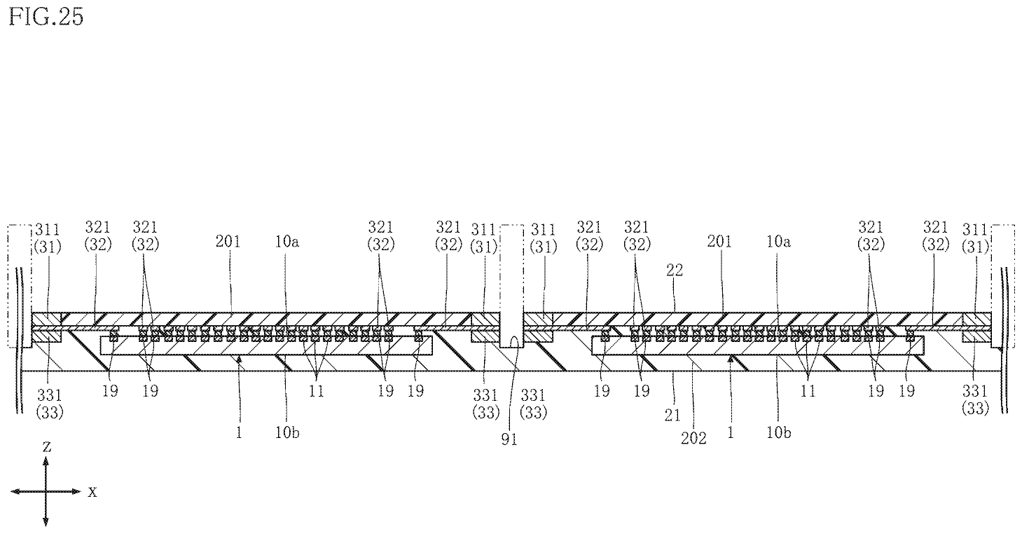

Next, as shown in FIGS. 24 and 25, a groove 91 in a lattice pattern in plan view is formed by half-cut dicing. FIG. 24 shows the state before half-cut dicing, and FIG. 25 shows the state after half-cut dicing. In FIG. 24, the region subjected to half-cut dicing is indicated by dots. In half-cut dicing, a dicing blade is moved in the directions shown by the arrows in FIG. 24 (first dicing directions), for example. As shown in FIG. 24, the first dicing direction along the first direction x refers to the direction in which the dicing blade travels from the second side in the first direction x to the first side in the first direction x. The first dicing direction along the second direction y refers to the direction in which the dicing blade travels from the second side in the second direction y to the first side in the second direction y. In FIG. 25, a region having undergone half-cut dicing is indicated by an imaginary line. In half-cut dicing, the dicing blade is first moved in the first dicing direction along the first direction x. The dicing is referred to as “preceding first dicing”. As a result of the preceding first dicing, a stripe portion of the groove 91 extending in the first direction x is formed, and the second exposed surface 412, the third exposed surface 421, the sixth exposed surface 432, and the seventh exposed surface 441 are formed in the stripe portion extending in the first direction X. Next, the dicing blade is moved in the first dicing direction along the second direction y. The dicing is referred to as “succeeding first dicing”. As a result of the succeeding first dicing, a stripe portion of the groove 91 extending in the second direction y is formed, and the first exposed surface 411, the fourth exposed surface 422, the fifth exposed surface 431, and the eighth exposed surface 442 are formed in the stripe portion extending in the second direction y. As shown in FIG. 25, the groove 91 formed by half-cut dicing extends over the resin member 2 (the first resin portion 201 and the second resin portion 202) as well as over the first conductive layer 31, the second conductive layer 32, and the third conductive layer 33.

Next, the surfaces of the first conductive layer 31, the second conductive layer 32, and the third conductive layer 33 exposed from the resin reverse surface 22 and the groove 91 are plated. In the present embodiment, a Ni layer, a Pd layer, and a Au layer are deposited in sequence by electroless plating. Specifically, plating layers each made of a Ni layer, a Pd layer, and a Au layer are formed on the first exposed surface 411, the second exposed surface 412, the reverse surface 414, the third exposed surface 421, the fourth exposed surface 422, the reverse surface 424, the fifth exposed surface 431, the sixth exposed surface 432, the reverse surface 434, the seventh exposed surface 441, the eighth exposed surface 442, and the reverse surface 444.

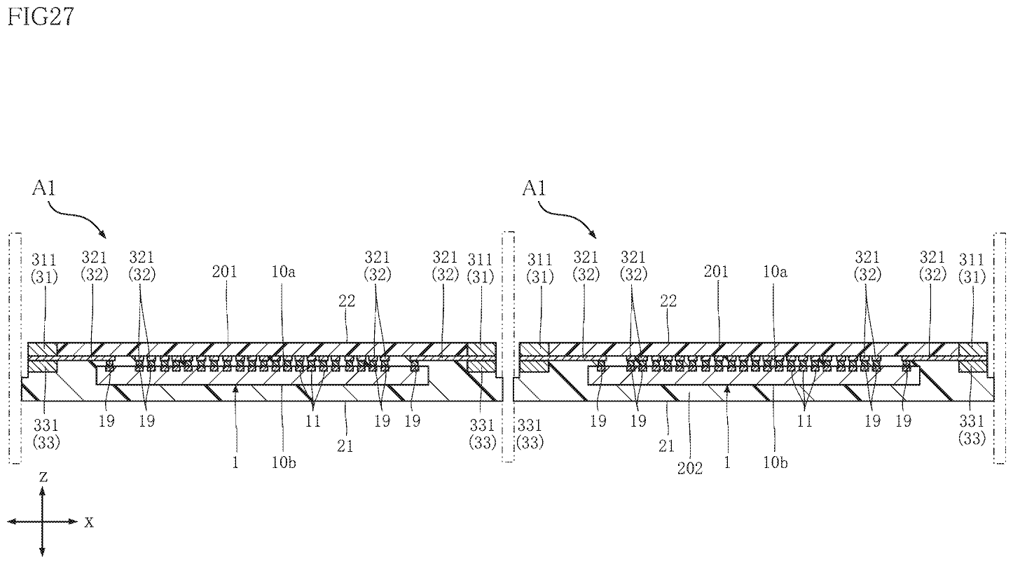

Next, as shown in FIGS. 26 and 27, the intermediate product is subjected to full-cut dicing (cutting) so that it is diced into pieces each including an electronic component 1. FIG. 26 shows the state before full-cut dicing, and FIG. 27 shows the state after full-cut dicing. In FIGS. 26 and 27, the region subjected to full-cut dicing is indicated by dots. In full-cut dicing, a dicing blade is moved in the direction shown by the arrow in FIG. 26 (second dicing directions), for example. As shown in FIG. 26, the second dicing direction along the first direction x refers to the direction in which the dicing blade travels from the second side in the first direction x to the first side in the first direction x. The second dicing direction along the second direction y refers to the direction in which the dicing blade travels from the second side in the second direction y to the first side in the second direction y. The dicing blade used in the full-cut dicing is thinner than the dicing blade used in the half-cut dicing. In FIG. 27, a region having undergone full-cut dicing is indicated by an imaginary line. In full-cut dicing, the dicing blade is moved in the second dicing direction along the first direction x. The dicing is referred to as “preceding second dicing”. The second side end surface 241 and the fourth side end surface 261 are formed as a result of the preceding second dicing. Next, the dicing blade is moved in the second dicing direction along the second direction y. The dicing is referred to as “succeeding second dicing”. The succeeding second dicing forms the first side end surface 231 and the third side end surface 251.

Through the processing steps as described above, a plurality of electronic devices A1, each identical to the one shown FIGS. 1 to 16, are formed. The method for manufacturing the electronic device A1 as described above is merely an example, and the present disclosure is not limited to this example.

The advantages of the electronic device A1 are described below.

The first corner terminal 41 of the electronic device A1 has the first exposed surface 411, the second exposed surface 412, and the first surface 413. The first exposed surface 411 is exposed from the first resin side surface 23, and the second exposed surface 412 is exposed from the second resin side surface 24. The first surface 413 is connected to the first exposed surface 411 and the second exposed surface 412, and is covered with the resin member 2. In the manufacturing method described above, the first exposed surface 411 is formed by the preceding first dicing in half-cut dicing, and the second exposed surface 412 is formed by the succeeding first dicing in half-cut dicing. Unlike this configuration, suppose that the first corner terminal 41 does not have the first surface 413, and the first exposed surface 411 and the second exposed surface 412 are directly connected to each other. In such a configuration, the end portions obtained by the preceding first dicing and the succeeding second dicing in half-cut dicing overlap with the corner at which the first exposed surface 411 and the second exposed surface 412 are connected to each other. In other words, in the configuration without the first surface 413, a processing load during dicing is applied twice in total to the corner at which the first exposed surface 411 and the second exposed surface 412 are connected to each other. Thus, the impact and stress applied to the first corner terminal 41 increases, and the possibility of peeling of the first corner terminal 41 increases. On the other hand, the electronic device A1 is configured such that the first corner terminal 41 has the first surface 413, and the first surface 413 is covered with the resin member 2. As such, the end portions obtained by the preceding first dicing and the succeeding first dicing contain the resin member 2 rather than the first corner terminal 41. This suppresses the impact and stress applied to the first corner terminal 41. Accordingly, the electronic device A1 can suppress peeling of the first corner terminal 41 from the resin member 2.

In the electronic device A1, the second corner terminal 42 has the second surface 423 connected to the third exposed surface 421 and the fourth exposed surface 422, the third corner terminal 43 has the third surface 433 connected to the fifth exposed surface 431 and the sixth exposed surface 432, and the fourth corner terminal 44 has the fourth surface 443 connected to the seventh exposed surface 441 and the eighth exposed surface 442. The second surface 423, the third surface 433, and the fourth surface 443 are covered with the resin member 2. According to this configuration, the electronic device A1 can suppress peeling of the second corner terminal 42, the third corner terminal 43, and the fourth corner terminal 44 from the resin member 2, as well as suppressing peeling of the first corner terminal 41 from the resin member 2. In other words, according to the electronic device A1, the terminals (the first corner terminal 41, the second corner terminal 42, the third corner terminal 43, and the fourth corner terminal 44) arranged near the four corners of the resin member 2 in plan view are suppressed from peeling from the resin member 2.

In the electronic device A1, each of the first exposed surface 411, the second exposed surface 412, the third exposed surface 421, the fourth exposed surface 422, the fifth exposed surface 431, the sixth exposed surface 432, the seventh exposed surface 441, the eighth exposed surface 442, the exposed surfaces 511, the exposed surfaces 521, the exposed surfaces 531, and the exposed surfaces 541 is formed with a plating layer. According to this configuration, when the electronic device A1 is mounted by soldering on the circuit board of an electronic device or the like, a fillet resulting from the build-up of solder is formed. In this way, when the electronic device A1 is mounted on a circuit board, the state of solder bonding can be visually inspected from above the circuit board, which means that visual inspection of the electronic device A1 is possible.

The first corner terminal 41 of the electronic device A1 includes a columnar portion 331. This configuration allows the first corner terminal 41 to have a larger dimension in the thickness direction z as compared to the configuration without a columnar portion 331. This makes it possible to increase the areas of the first exposed surface 411 and the second exposed surface 412. When the electronic device A1 is mounted on the circuit board of an electronic device or the like, a bonding material, such as solder, makes contact with the first exposed surface 411 and the second exposed surface In other words, since the contact area of the bonding 412. material increases, the electronic device A1 can increase the bonding strength with respect to the circuit board of an electronic device or the like. This also applies to the second corner terminal 42, the third corner terminal 43, the fourth corner terminal 44, the first side terminals 51, the second side terminals 52, the third side terminals 53, and the fourth side terminals 54.

The first corner terminal 41 of the electronic device A1 is not electrically connected to the electronic component 1. The first corner terminal 41 not electrically connected to the electronic component 1 may not be provided for the electronic device A1 from an electrical point of view. However, with the first corner terminal 41, the electronic device A1 can increase the bonding area for solder or the like when the circuit board of an electronic device or the like is mounted. In other words, with the first corner terminal 41, the electronic device A1 can increase the mounting strength with respect to the circuit board of an electronic device or the like. This also applies to the second corner terminal 42, the third corner terminal 43, and the fourth corner terminal 44.

Next, electronic devices A2 to A6 according to variations of the first embodiment will be described.

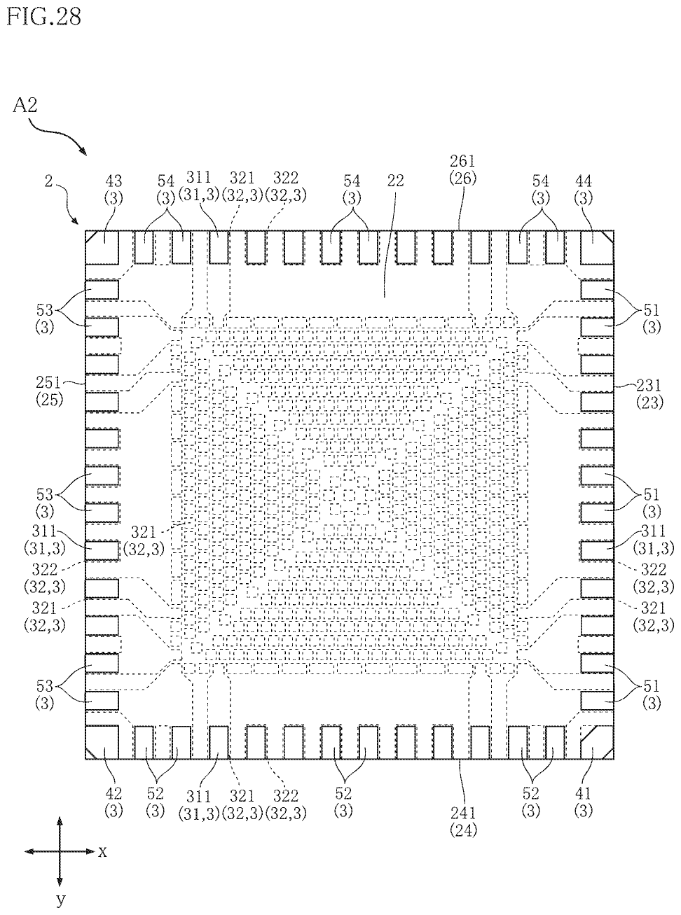

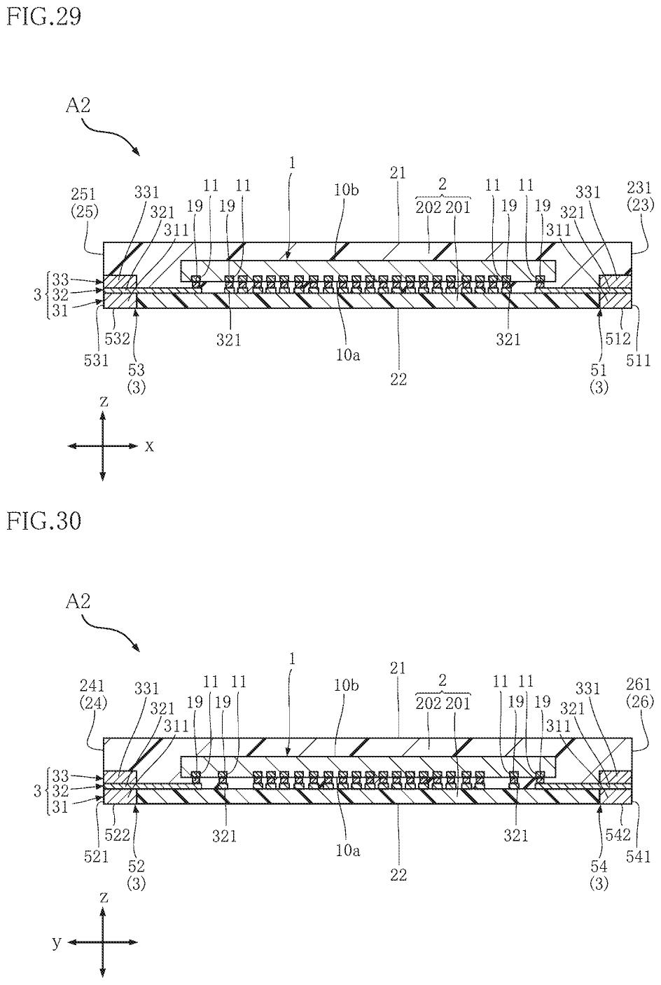

FIGS. 28 to 30 show an electronic device A2 according to a first variation of the first embodiment. The electronic device A2 is different from the electronic device A1 in the following points. Firstly, the first resin side surface 23 of the electronic device A2 does not include the first resin recess 232. Secondly, the second resin side surface 24 of the electronic device A2 does not include the second resin recess 242. Thirdly, the third resin side surface 25 of the electronic device A2 does not include the third resin recess 252. Fourthly, the fourth resin side surface 26 of the electronic device A2 does not include the fourth resin recess 262.

The electronic device A2 shown in FIGS. 28 to 30 can be manufactured by not performing half-cut dicing in the manufacturing method of the electronic device A1, for example.

The manufacturing method of the electronic device A2 half-cut dicing. Accordingly, the does not involve aforementioned electroless plating is used to deposit a plating layer (e.g., a Ni layer, a Pd layer, and a Au layer) on the reverse surface 414 of the first corner terminal 41, the reverse surface 424 of the second corner terminal 42, the reverse surface 434 of the third corner terminal 43, the reverse surface 444 of the fourth corner terminal 44, the reverse surfaces 512 of the first side terminals 51, the reverse surfaces 522 of the second side terminals 52, the reverse surfaces 532 of the third side terminals 53, and the reverse surfaces 542 of the fourth side terminals 54.

Since half-cut dicing is not performed in the manufacturing method of the electronic device A2, the first exposed surface 411 and the second exposed surface 412 are formed at the first corner terminal 41 by full-cut dicing. As a result of the full-cut dicing, the third exposed surface 421 and the fourth exposed surface 422 are formed at the second corner terminal 42, the fifth exposed surface 431 and the sixth exposed surface 432 are formed at the third corner terminal 43, and the seventh exposed surface 441 and the eighth exposed surface 442 are formed at the fourth corner terminal 44.

The electronic device A2 is similar to the electronic device A1 in that the first corner terminal 41 has the first surface 413, and the first surface 413 is connected to the first exposed surface 411 and the second exposed surface 412 and covered with the resin member 2. Thus, as with the electronic device A1, the electronic device A2 can suppress peeling of a terminal (such as the first corner terminal 41) exposed from the resin member 2. This also applies to the second corner terminal 42, the third corner terminal 43, and the fourth corner terminal 44. Note that the electronic device A2 has advantages common to the electronic device A1 owing to its common configuration with the electronic device A1.

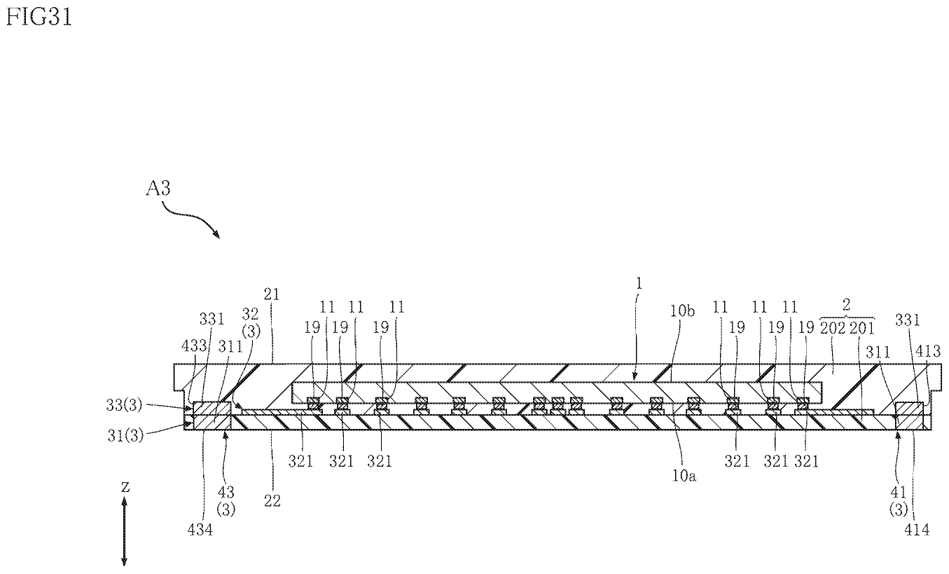

FIG. 31 shows an electronic device A3 according to a second variation of the first embodiment. The electronic device A3 is different from the electronic device A1 in that the second conductive layer 32 does not include the intervening portions 322.

As shown in FIG. 31, in the electronic device A3, the columnar portion 331 of each of the first corner terminal 41 and the third corner terminal 43 is formed on and in contact with the corresponding columnar portion 311. Similarly, the columnar portion 331 of each of the second corner terminal 42 and the fourth corner terminal 44 is formed on and in contact with the corresponding columnar portion 311. Furthermore, some of the first side terminals 51, the second side terminals 52, the third side terminals 53, and the fourth side terminals 54, which are not electrically connected to the electronic component 1, are each configured such that the columnar portion 331 is formed on and in contact with the columnar portion 311.

The electronic device A3 is similar to the electronic device A1 in that the first corner terminal 41 has the first surface 413, and the first surface 413 is connected to the first exposed surface 411 and the second exposed surface 412 and covered with the resin member 2. Thus, as with the electronic device A1, the electronic device A3 can suppress peeling of a terminal (such as the first corner terminal 41) exposed from the resin member 2. This also applies to the second corner terminal 42, the third corner terminal 43, and the fourth corner terminal 44. Note that the electronic device A3 has advantages common to each of the electronic devices A1 and A2 owing to its common configuration with each of the electronic devices A1 and A2.

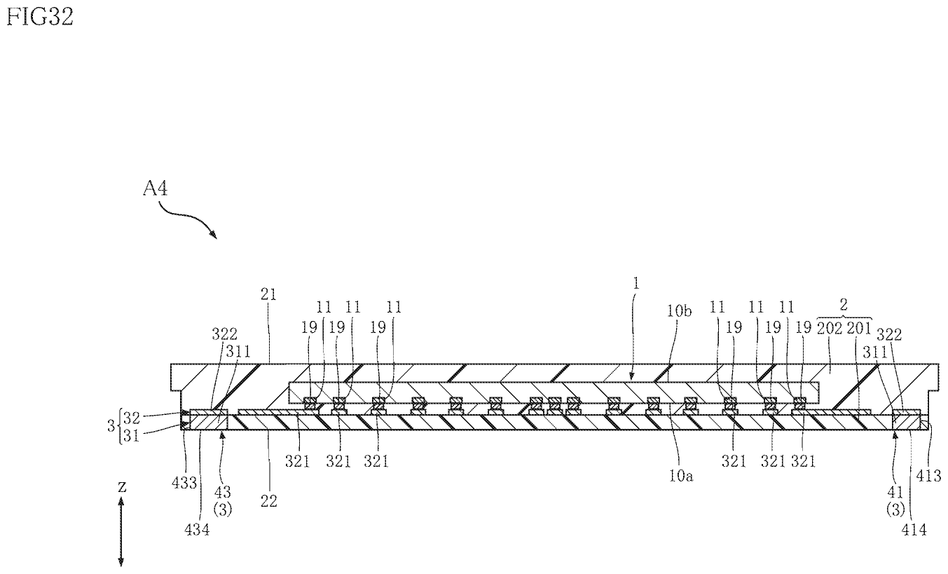

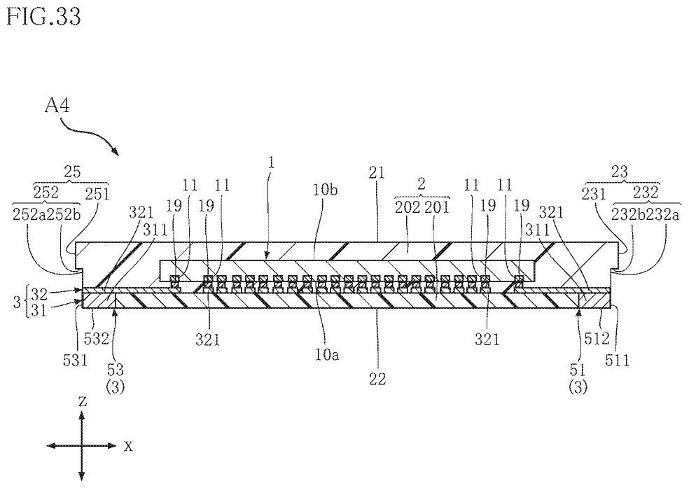

FIGS. 32 and 33 show an electronic device A4 according to a third variation of the first embodiment. The electronic device A4 is different from the electronic device A1 in not including the third conductive layer 33 (the columnar portions 331).

Since the conductive member 3 of the electronic device A4 does not include the third conductive layer 33, the columnar portions 331 are not formed on the intervening portions 322 of the first corner terminal 41 and the third corner terminal 43, as shown in FIG. 32. Similarly, the columnar portions 331 are not formed on the intervening portions 322 of the second corner terminal 42 and the fourth corner terminal 44. Furthermore, as can be understood from FIG. 33, the first side terminals 51, the second side terminals 52, the third side terminals 53, and the fourth side terminals 54 are configured such that the columnar portions 331 are not formed on either the wiring portions 321 or the intervening portions 322.

The electronic device A4 is similar to the electronic device A1 in that the first corner terminal 41 has the first surface 413, and the first surface 413 is connected to the first exposed surface 411 and the second exposed surface 412 and covered with the resin member 2. Thus, as with the electronic device A1, the electronic device A4 can suppress peeling of a terminal (such as the first corner terminal 41) exposed from the resin member 2. This also applies to the second corner terminal 42, the third corner terminal 43, and the fourth corner terminal 44. However, in the electronic device A1, for example, the areas of the first exposed surface 411 and the second exposed surface 412 of the first corner terminal 41 are increased by the respective columnar portions 331. As such, the electronic device A1 has an increased mounting strength with respect to the circuit board of an electronic device or the like. The improvement of the mounting strength owing to the columnar portions 331 as described above is the same for the second corner terminal 42, the third corner terminal 43, the fourth corner terminal 44, the first side terminals 51, the second side terminals 52, the third side terminals 53, and the fourth side terminals 54. Accordingly, in view of the improvement of mounting strength, the electronic device A1 is more preferable to the electronic device A4. Note that the electronic device A4 has advantages common to each of the electronic devices A1 to A3 owing to its common configuration with each of the electronic devices A1 to A3.

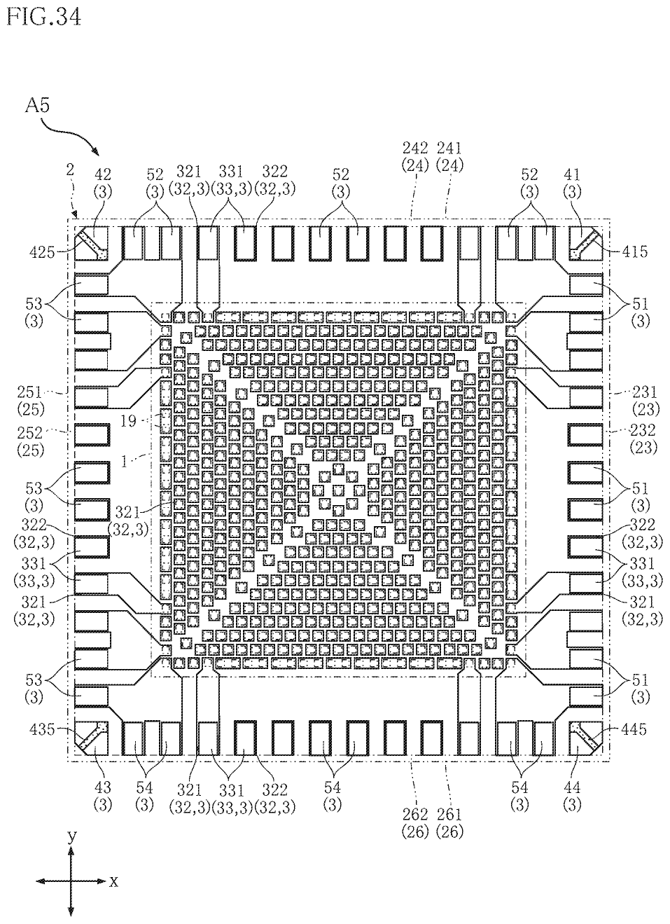

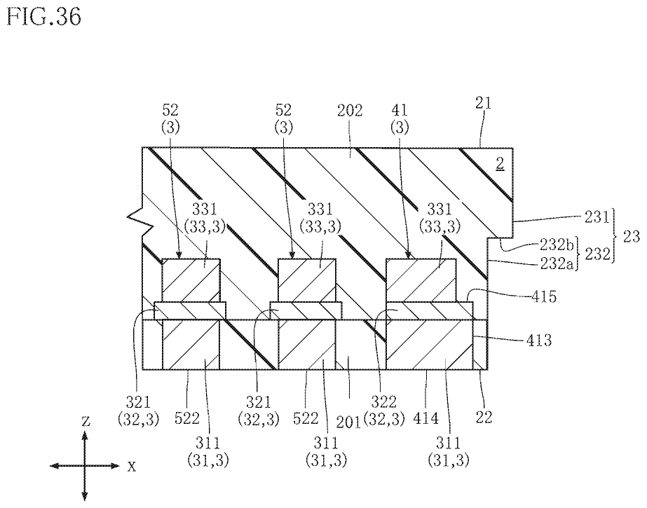

FIGS. 34 to 36 show an electronic device A5 according to a fourth variation of the first embodiment. The electronic device A5 is different from the electronic device A1 in the shape of the columnar portion 331 of each of the first corner terminal 41, the second corner terminal 42, the third corner terminal 43, and the fourth corner terminal 44.

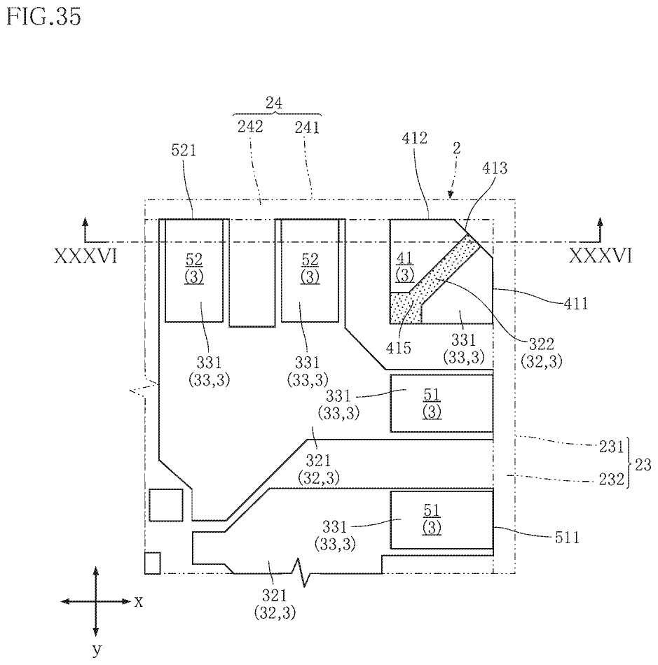

As shown in FIGS. 34 and 35, the first corner terminal 41 of the electronic device A5 has a columnar portion 331 divided into two sections. Accordingly, the first corner terminal 41 further includes an exposed region 415. For convenience of understanding, the exposed region 415 is shaded with dots in FIGS. 34 and 35. The exposed region 415 is exposed from the columnar portion 331 of the first corner terminal 41 in plan view. According to the present embodiment, the exposed region 415 is a part of the upper surface (the surface facing upward in the thickness direction z) of the intervening portion 322. Unlike this configuration, as can be seen in the electronic device A3, when the first corner terminal 41 does not include the intervening portion 322, the exposed region 415 is a part of the upper surface (the surface facing upward in the thickness direction z) of the columnar portion 311. The exposed region 415 overlaps with the first surface 413 in plan view. The exposed region 415 extends in a direction perpendicular to the first surface 413 in plan view.

As shown in FIG. 34, the second corner terminal 42 of the electronic device A5 further includes an exposed region 425. The third corner terminal 43 further includes an exposed region 435. The fourth corner terminal 44 further includes an exposed region 445. In FIG. 34, the exposed regions 425, 435, and 445 are shaded with dots. The exposed region 425 is exposed from the columnar portion 331 of the second corner terminal 42 in plan view. The exposed region 435 is exposed from the columnar portion 331 of the third corner terminal 43 in plan view. The exposed region 445 is exposed from the columnar portion 331 of the fourth corner terminal 44 in plan view. Each of the exposed regions 425, 435, and 445 is configured similarly to the exposed region 415 in plan view.

The electronic device A5 is similar to the electronic device A1 in that the first corner terminal 41 has the first surface 413, and the first surface 413 is connected to the first exposed surface 411 and the second exposed surface 412 and covered with the resin member 2. Thus, as with the electronic device A1, the electronic device A5 can suppress peeling of a terminal (such as the first corner terminal 41) exposed from the resin member 2. This also applies to the second corner terminal 42, the third corner terminal 43, and the fourth corner terminal 44. Note that the electronic device A5 has advantages common to each of the electronic devices A1 to A4 owing to its common configuration with each of the electronic devices A1 to A4.

In the electronic device A5, the columnar portion 331 of the first corner terminal 41 is divided into two sections, and the first corner terminal 41 further includes the exposed region 415. According to the configuration, the resin member 2 is formed in contact with the exposed region 415. Thus, the electronic device A5 can increase the adhesive strength between the resin member 2 and the first corner terminal 41 by an anchor effect. In other words, the electronic device A5 can further suppress peeling of the first corner terminal 41 as compared to the electronic device A1. This also applies to the second corner terminal 42, the third corner terminal 43, and the fourth corner terminal 44.

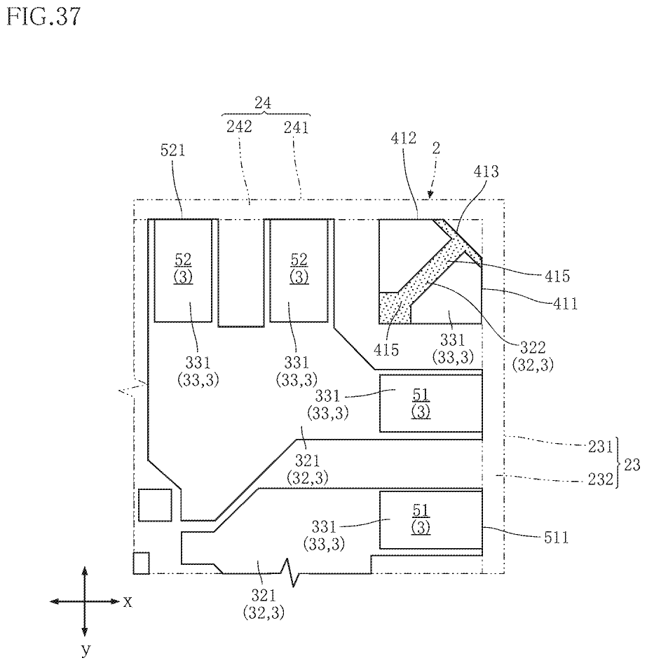

In the electronic device A5, the shape of the columnar portion 331 of each of the first corner terminal 41, the second corner terminal 42, the third corner terminal 43, and the fourth corner terminal 44 is not limited to the example shown in FIGS. 34 to 36. FIG. 37 shows an example where the columnar portion 331 of the first corner terminal 41 has a shape different from the example shown in the electronic device A5. The exposed region 415 of the columnar portion 331 in the first corner terminal 41 shown in FIG. 37 includes a region along the first surface 413 in plan view, as compared to the one shown in FIG. 35. The electronic device shown in FIG. 37 also has the same effect as the electronic device A5.

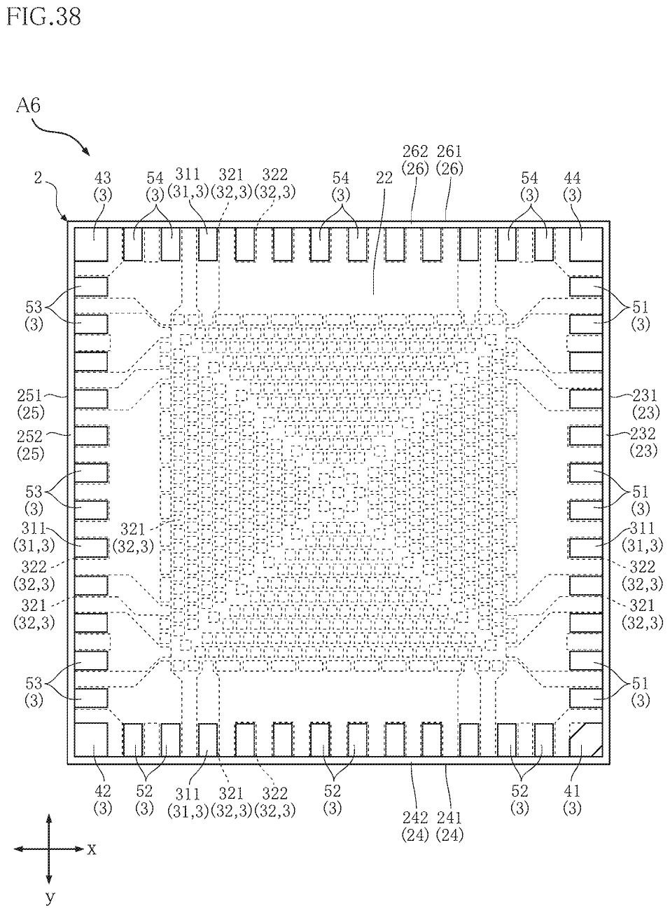

FIG. 38 shows an electronic device A6 according to a fifth variation of the first embodiment. The electronic device A6 is different from the electronic device A1 in the following points. Firstly, the second corner terminal 42 of the electronic device A6 does not have the second surface 423. Secondly, the third corner terminal 43 of the electronic device A6 does not have the third surface 433. Thirdly, the fourth corner terminal 44 of the electronic device A6 does not have the fourth surface 443.

In the manufacturing method of the electronic device A6, the first corner terminal 41 is cut after the second corner terminal 42, the third corner terminal 43, and the fourth corner terminal 44 is cut in half-cut dicing, for example. In this configuration, the vibrations and stress applied to the first corner terminal 41 during dicing are greater than the vibrations and stress applied to each of the second corner terminal 42, the third corner terminal 43, and the fourth corner terminal 44. In other words, there is a high possibility that the first corner terminal 41 peels off from the resin member 2. Accordingly, in the electronic device A6, only the first corner terminal 41 having a higher possibility of peeling is provided with the first surface 413.

The electronic device A6 is similar to the electronic device A1 in that the first corner terminal 41 has the first surface 413, and the first surface 413 is connected to the first exposed surface 411 and the second exposed surface 412 and covered with the resin member 2. Thus, as with the electronic device A1, the electronic device A6 can suppress peeling of a terminal (such as the first corner terminal 41) exposed from the resin member 2. Note that the electronic device A6 has advantages common to each of the electronic devices A1 to A5 owing to its common configuration with each of the electronic devices A1 to A5.

The electronic device A6 has been described with an example where only the first corner terminal 41 having the highest possibility of peeling from the resin member 2 is provided with the first surface 413. However, it is possible to further provide the second corner terminal 42 with the second surface 423, the third corner terminal 43 with the third surface 433, and/or the fourth corner terminal 44 with the fourth surface 443. For example, of the first corner terminal 41, the second corner terminal 42, the third corner terminal 43, and the fourth corner terminal 44, two (or three) corner terminals having higher possibilities of peeling from the resin member 2 are selected. In one example, the two corner terminals having higher possibilities of peeling are the first corner terminal 41 and the fourth corner terminal 44, which are to be cut in the succeeding first dicing. Then, each of the selected corner terminals may be provided with one of the first surface 413, the second surface 423, the third surface 433, and the fourth surface 443 as appropriate. In other words, one having a lower possibility of peeling from the resin member 2 may not need to be formed with the first surface 413, the second surface 423, the third surface 433, or the fourth surface 443.

### Second Embodiment

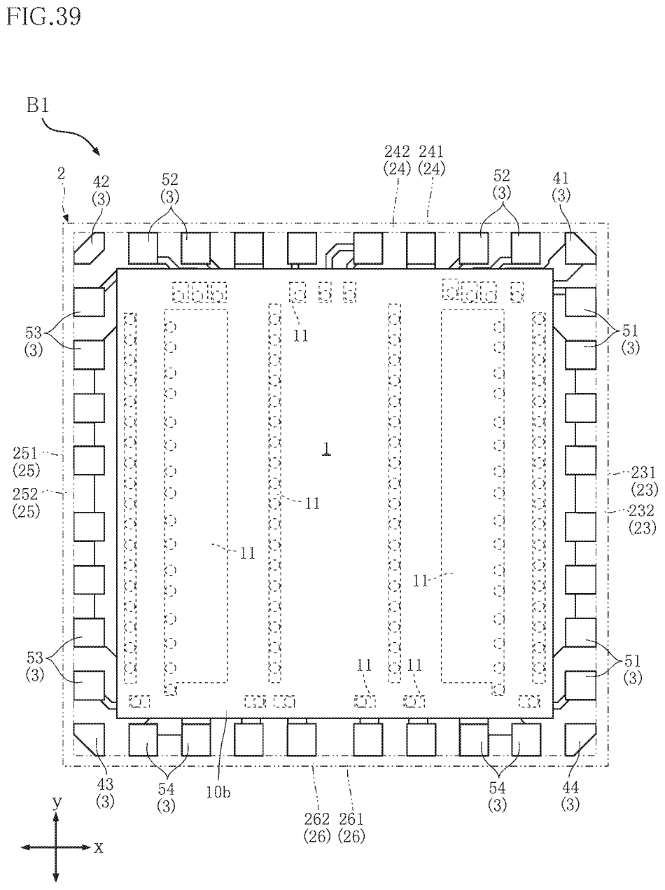

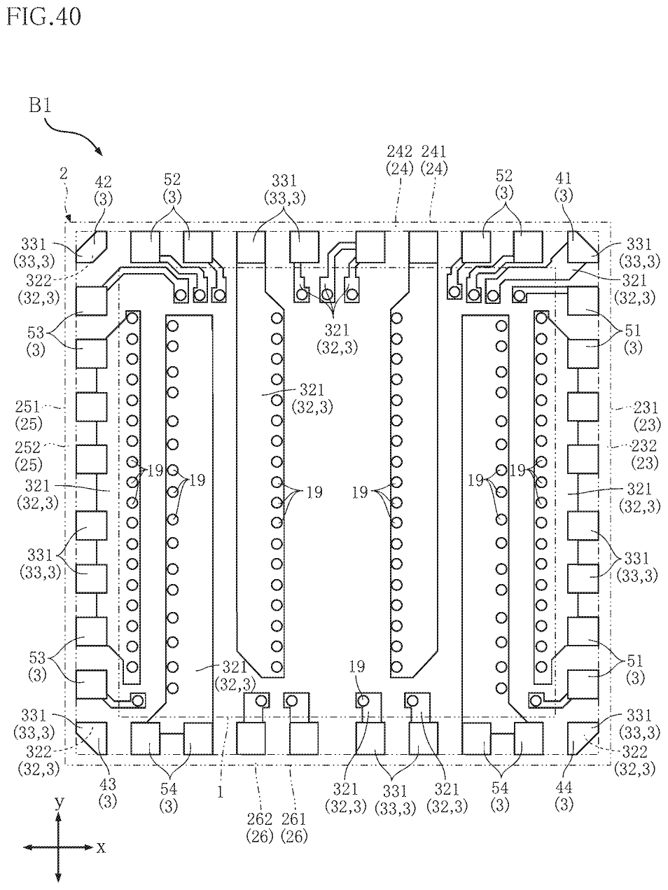

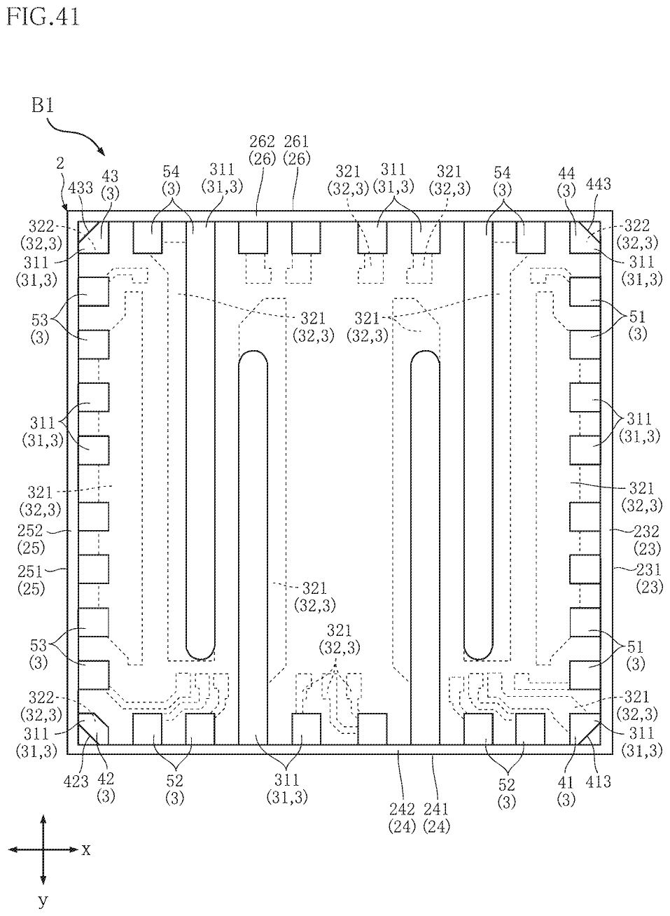

FIGS. 39 to 41 show an electronic device B1 according to a second embodiment. The electronic device B1 is different from the electronic device A1 in the following points. Firstly, the electronic device B1 is different mainly in the configuration of the conductive member 3.

As shown in FIGS. 39 to 41, the first corner terminal 41 of the electronic device B1 is electrically connected to the electronic component 1. Accordingly, the first corner terminal 41 includes a wiring portion 321 instead of an intervening portion 322, as compared to the first corner terminal 41 in the electronic device A1. Furthermore, as shown in FIGS. 39 9 to 41, the electronic device B1 is configured such that all of the first side terminals 51, the second side terminals 52, the third side terminals 53, and the fourth side terminals 54 are electrically connected to the electronic component 1.

The electronic device B1 is similar to the electronic device A1 in that the first corner terminal 41 has the first surface 413. According to this configuration, the electronic device B1 can suppress peeling of the first corner terminal 41 from the resin member 2, similarly to the electronic device A1. Furthermore, the electronic device B1 is similar to the electronic device A1 in that the second corner terminal 42 has the second surface 423, the third corner terminal 43 has the third surface 433, and the fourth corner terminal 44 has the fourth surface 443. Accordingly, the electronic device B1 can suppress peeling of the second corner terminal 42, the third corner terminal 43, and the fourth corner terminal 44 from the resin member 2, similarly to the electronic device A1. Note that the electronic device B1 has advantages common to each of the electronic devices A1 to A6 owing to its common configuration with each of the electronic devices A1 to A6.

### Third Embodiment

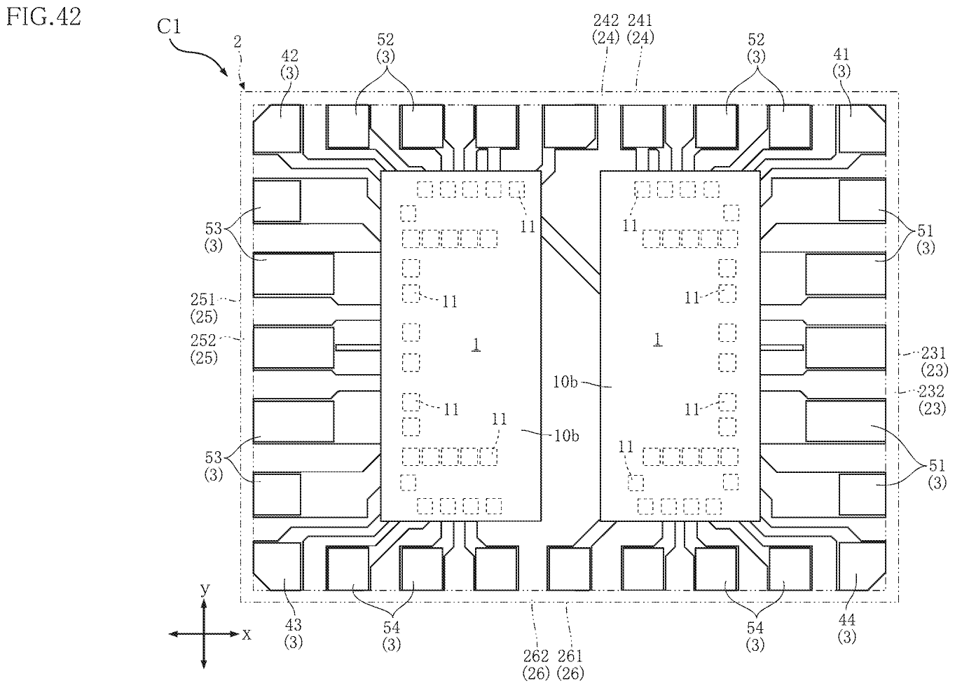

FIGS. 42 to 44 show an electronic device C1 according to a third embodiment. The electronic device Cl is different from each of the electronic devices A1 and B1 in the following points. Firstly, the electronic device C1 includes two electronic components 1. Secondly, in the electronic device C1, the first corner terminal 41, the second corner terminal 42, the third corner terminal 43, and the fourth corner terminal 44 are electrically connected to the electronic component 1.

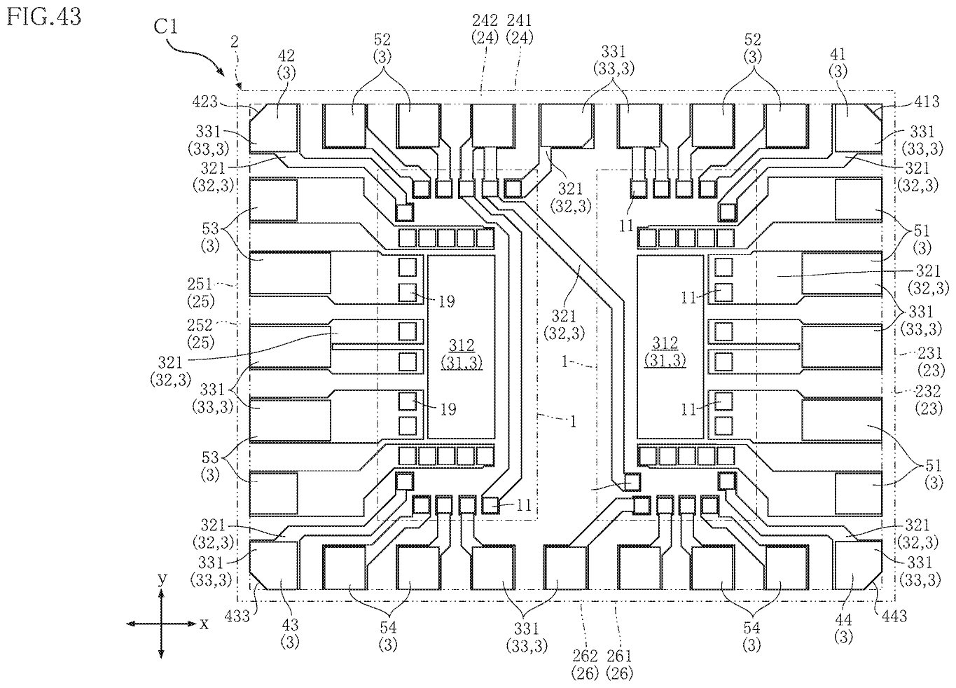

As shown in FIGS. 42 and 43, the two electronic components 1 are spaced apart from each other in the first direction x, for example.

As shown in FIGS. 42 to 44, in the electronic device C1, each of the first corner terminal 41, the second corner terminal 42, the third corner terminal 43, the fourth corner terminal 44, the first side terminals 51, the second side terminals 52, the third side terminals 53, and the fourth side terminals 54 is electrically connected to one of the two electronic components 1. In the electronic device C1 having this configuration, the second conductive layer 32 of the conductive member 3 does not include the intervening portions 322, and each of the first corner terminal 41, the second corner terminal 42, the third corner terminal 43, the fourth corner terminal 44, the first side terminals 51, the second side terminals 52, the third side terminals 53, and the fourth side terminals 54 includes a wiring portion 321 instead of an intervening portion 322.

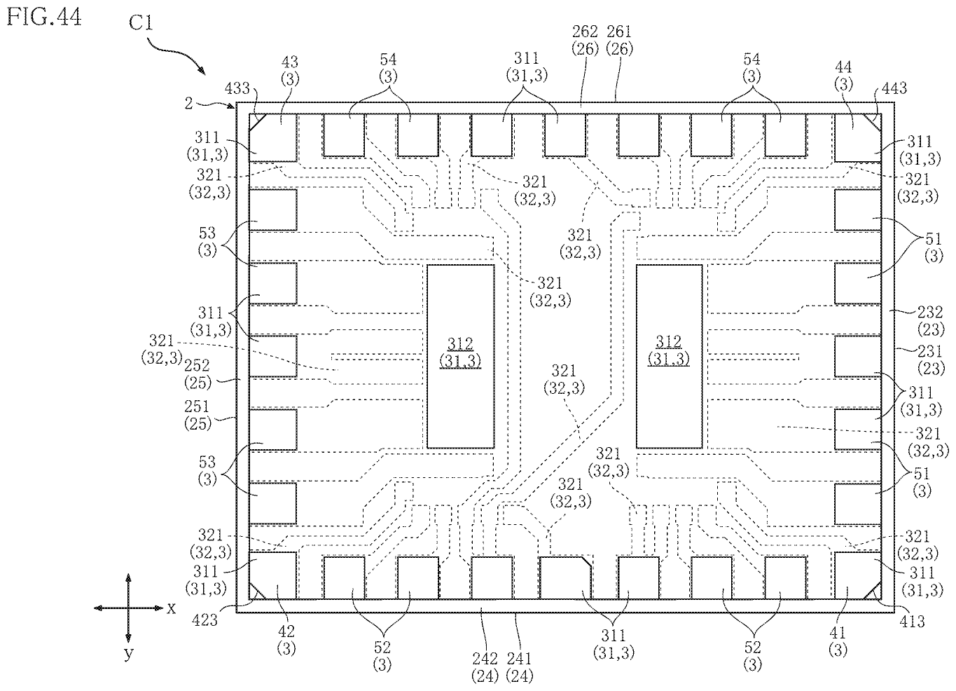

As shown in FIGS. 43 and 44, in the electronic device C1, the first conductive layer 31 of the conductive member 3 includes two plate-like portions 312. The two plate-like portions 312 are arranged under the two electronic components 1. One of the two plate-like portions 312 overlaps with one of the two electronic components 1 in plan view, and the other plate-like portion 312 overlaps with the other electronic component 1 in plan view. The plate-like portions 312 function as heat sinks that release heat from the respective electronic components 1. Note that the electronic device C1 may not be provided with the plate-like portions 312. Alternatively, each of the plate-like portions 312 may be used as a terminal electrically connected to one of the two electronic components 1.

The electronic device C1 is similar to the electronic device A1 in that the first corner terminal 41 has the first surface 413. According to this configuration, the electronic device C1 can suppress peeling of the first corner terminal 41 from the resin member 2, similarly to the electronic device A1. Furthermore, the electronic device C1 is similar to the electronic device A1 in that the second corner terminal 42 has the second surface 423, the third corner terminal 43 has the third surface 433, and the fourth corner terminal 44 has the fourth surface 443. Accordingly, the electronic device C1 can suppress peeling of the second corner terminal 42, the third corner terminal 43, and the fourth corner terminal 44 from the resin member 2, similarly to the electronic device A1. Note that the electronic device C1 has advantages common to each of the electronic devices A1 to A6 and B1 owing to its common configuration with each of the electronic devices A1 to A6 and B1.

As can be understood from the electronic devices B1 and C1, the electronic device of the present disclosure is not limited to the configuration where none of the first corner terminal 41, the second corner terminal 42, the third corner terminal 43, and the fourth corner terminal 44 is electrically connected to the electronic component 1, and may be configured such that at least one of the first corner terminal 41, the second corner terminal 42, the third corner terminal 43, and the fourth corner terminal 44 is electrically connected to the electronic component 1. Furthermore, as can be understood from the electronic device C1, the electronic device of the present disclosure is not limited to the configuration with a single electronic component 1, and may include a plurality of electronic components 1. According to the electronic device of the present disclosure, the configuration of the conductive member 3 can be changed appropriately according to the type and number of the electronic component 1. The type in this context may refer to an element such as an integrated circuit element or a discrete element (e.g., an active functional element or a passive functional element).

Each of the second embodiment and the third embodiment can include any of the configurations according to the variations (the second to fifth variations) of the first embodiment as appropriate. In other words, each of the electronic devices B1 and C1 can include the configuration according to any of the configurations according to the electronic devices A2 to A6. For example, as with the electronic device A2, each of the electronic devices B1 and C1 may have a configuration where the first resin side surface 23 does not include the first side end surface 231. As with the electronic device A3, each of the electronic devices B1 and C1 may have a configuration where the second conductive layer 32 does not include the intervening portions 322. As with the electronic device A4, each of the electronic devices B1 and C1 may have a configuration where the conductive member 3 does not include the third conductive layer 33. As with the electronic device A5, each of the electronic devices B1 and C1 may have a configuration where the first corner terminal 41, the second corner terminal 42, the third corner terminal 43, and the fourth corner terminal 44 are provided with the respective exposed regions 415, 425, 435, and 445 exposed from the respective columnar portions 331. As with the electronic device A6, each of the electronic devices B1 and C1 may have a configuration where the second corner terminal 42 is not provided with the second surface 423, the third corner terminal 43 is not provided with the third surface 433, the fourth corner terminal 44 is not provided with the fourth surface 443, and the first corner terminal 41 is provided with the first surface 413.

Although the electronic component 1 is flip-chip mounted according to an example given in the first embodiment to the third embodiment, it may be mounted with a bonding wire instead. In this configuration, the electronic component 1 is arranged such that the element reverse surface 10b faces the conductive member 3. Furthermore, the conductive member 3 is provided with an island to which the electronic component 1 is bonded, as appropriate.

The electronic device according to the present disclosure is not limited to the above embodiments. Various design changes can be made to the specific configurations of the elements of the electronic device of the present disclosure. For example, the present disclosure includes the embodiments described in the following clauses.

Clause 1.

An electronic device comprising:
an electronic component;
a resin member covering the electronic component; and
a conductive member supported by the resin member,
wherein the resin member includes a first resin side surface and a second resin side surface that intersect with each other,
the conductive member includes a first corner terminal including a first exposed surface exposed from the first resin side surface and a second exposed surface exposed from the second resin side surface,
the first corner terminal includes a first surface connected to the first exposed surface and the second exposed surface as viewed in a thickness direction of the resin member, and
the first surface is covered with the resin member.

Clause 2.

The electronic device according to clause 1,
wherein the first surface is a flat surface, and is inclined relative to the first exposed surface and the second exposed surface as viewed in the thickness direction.

Clause 3.

The electronic device according to clause 1 or 2,
wherein the resin member includes a resin obverse surface and a resin reverse surface spaced apart from each other in the thickness direction, and
the first corner terminal is exposed from the resin reverse surface.

Clause 4.

The electronic device according to clause 3,
wherein the resin member includes a first resin portion and a second resin portion that are stacked in the thickness direction and make contact with each other,
the first resin portion includes the resin reverse surface, and
the second resin portion has the resin obverse surface.

Clause 5.

The electronic device according to clause 4,
wherein the conductive member includes a first conductive layer passing through the first resin portion in the thickness direction, and
the first corner terminal includes a first columnar portion that is a part of the first conductive layer.

Clause 6.

The electronic device according to clause 5,
wherein the conductive member includes a second conductive layer arranged between the first resin portion and the second resin portion in the thickness direction, and
the second conductive layer is electrically connected to the first conductive layer.

Clause 7.

The electronic device according to clause 6,
wherein the conductive member includes a third conductive layer formed on an opposite side from the first conductive layer relative to the second conductive layer in the thickness direction, and
the first corner terminal includes a second columnar portion that is a part of the third conductive layer.

Clause 8.

The electronic device according to clause 7,
wherein the first terminal corner includes an intervening portion that is a part of the second conductive layer and arranged between the first columnar portion and the second columnar portion.

Clause 9.

The electronic device according to clause 7 or 8,
wherein the first corner terminal has an exposed region exposed from the second columnar portion as viewed in the thickness direction.

Clause 10.

The electronic device according to clause 9,
wherein the exposed region is connected to the first surface as viewed in the thickness direction.

Clause 11.

The electronic device according to any of clauses 6 to 10,
wherein the electronic component includes an element obverse surface and an element reverse surface spaced apart from each other in the thickness direction, and an electrode formed on the element obverse surface,
the element obverse surface faces the second conductive layer, and
the electrode is bonded to the second conductive layer.

Clause 12.

The electronic device according to any of clauses 3 to 11,
wherein the first resin side surface faces a first side in a first direction perpendicular to the thickness direction, and
the second resin side surface faces a first side in a second direction perpendicular to the thickness direction and the first direction.

Clause 13.

The electronic device according to clause 12,
wherein the resin member includes a third resin side surface intersecting with the second resin side surface and facing away from the first resin side surface in the first direction, and a fourth resin side surface intersecting with the first resin side surface and facing away from the second resin side surface in the second direction, and
the third resin side surface and the fourth resin side surface intersect with each other.

Clause 14.

The electronic device according to clause 13,
wherein the resin member includes a first resin recess recessed from the resin reverse surface and connected to the first resin side surface, a second resin recess recessed from the resin reverse surface and connected to the second resin side surface, a third resin recess recessed from the resin reverse surface and connected to the third resin side surface, and a fourth resin recess recessed from the resin reverse surface and connected to the fourth resin side surface.

Clause 15.

The electronic device according to clause 13 or 14,
wherein the conductive member includes a second corner terminal, a third corner terminal, and a fourth corner terminal exposed from the resin reverse surface,
the second corner terminal includes a third exposed surface exposed from the second resin side surface and a fourth exposed surface exposed from the third resin side surface,
the third corner terminal includes a fifth exposed surface exposed from the third resin side surface and a sixth exposed surface exposed from the fourth resin side surface, and
the fourth corner terminal includes a seventh exposed surface exposed from the fourth resin side surface and an eighth exposed surface exposed from the first resin side surface.

Clause 16.

The electronic device according to clause 15,
wherein the second corner terminal includes a second surface connected to the third exposed surface and the fourth exposed surface as viewed in the thickness direction and covered with the resin member,
the third corner terminal includes a third surface connected to the fifth exposed surface and the sixth exposed surface as viewed in the thickness direction and covered with the resin member, and
the fourth corner terminal includes a fourth surface connected to the seventh exposed surface and the eighth exposed surface as viewed in the thickness direction and covered with the resin member.

Clause 17.

The electronic device according to any of clauses 13 to 16,
wherein the conductive member includes at least one side terminal exposed from one of the first resin side surface, the second resin side surface, the third resin side surface, and the fourth resin side surface.

Clause 18.

The electronic device according to clause 17,
wherein the at least one side terminal is electrically connected to the electronic component.

Clause 19.

The electronic device according to any of clauses 1 to 18,
wherein the first corner terminal is electrically insulated from the electronic component.

Clause 20.

The electronic device according to any of clauses 1 to 19,
wherein the electronic component is a semiconductor element made of a semiconductor material.

| | |
|---|---|
| A1-A6, B1, C1: Electronic device | |
| 1: Electronic component | 10a: Element obverse surface |
| 10b: Element reverse surface | 11: Electrode |
| 19: Bonding layer | 2: Resin member |
| 201: First resin portion | 202: Second resin portion |
| 21: Resin obverse surface | 22: Resin reverse surface |
| 23: First resin side surface | 231: First side end surface |
| 232: First resin recess | 232a: First wall surface |
| 232b: First bottom surface | 24: Second resin side surface |
| 241: Second side end surface | 242: Second resin recess |
| 242a: Second wall surface | 242b: Second bottom surface |
| 25: Third resin side surface | 251: Third side end surface |
| 252: Third resin recess | 252a: Third wall surface |
| 252b: Third bottom surface | 26: Fourth resin side surface |
| 261: Fourth side end surface | 262: Fourth resin recess |
| 262a: Fourth wall surface | 262b: Fourth bottom surface |
| 3: Conductive member | 31: First conductive layer |
| 311: Columnar portion | 312: Plate-like portion |
| 32: Second conductive layer | 321: Wiring portion |
| 322: Intervening portion | 33: Third conductive layer |
| 331: Columnar portion | 41: First corner terminal |
| 411: First exposed surface | 412: Second exposed surface |
| 413: First surface | 414: Reverse surface |
| 415: Exposed region | 419: Covered surface |
| 42: Second corner terminal | 421: Third exposed surface |
| 422: Fourth exposed surface | 423: Second surface |
| 424: Reverse surface | 425: Exposed region |
| 43: Third corner terminal | 431: Fifth exposed surface |
| 432: Sixth exposed surface | 433: Third surface |
| 434: Reverse surface | 435: Exposed region |
| 44: Fourth corner terminal | 441: Seventh exposed surface |
| 442: Eighth exposed surface | 443: Fourth surface |
| 444: Reverse surface | 445: Exposed region |
| 51: First side terminal | 511: Exposed surface |
| 512: Reverse surface | 52: Second side terminal |
| 521: Exposed surface | 522: Reverse surface |
| 53: Third side terminal | 531: Exposed surface |
| 532: Reverse surface | 54: Fourth side terminal |
| 541: Exposed surface | 542: Reverse surface |
| 90: Support substrate | 91: Groove |

1. An electronic device comprising:
an electronic component;
a resin member covering the electronic component; and
a conductive member supported by the resin member,
wherein the resin member includes a first resin side surface and a second resin side surface that intersect with each other,
the conductive member includes a first corner terminal including a first exposed surface exposed from the first resin side surface and a second exposed surface exposed from the second resin side surface,
the first corner terminal includes a first surface connected to the first exposed surface and the second exposed surface as viewed in a thickness direction of the resin member, and
the first surface is covered with the resin member.

2. The electronic device according to claim 1, wherein the first surface is a flat surface, and is inclined relative to the first exposed surface and the second exposed surface as viewed in the thickness direction.

3. The electronic device according to claim 1, wherein the resin member includes a resin obverse surface and a resin reverse surface spaced apart from each other in the thickness direction, and
the first corner terminal is exposed from the resin reverse surface.

4. The electronic device according to claim 3, wherein the resin member includes a first resin portion and a second resin portion that are stacked in the thickness direction and make contact with each other,
the first resin portion includes the resin reverse surface, and
the second resin portion includes the resin obverse surface.

5. The electronic device according to claim 4, wherein the conductive member includes a first conductive layer passing through the first resin portion in the thickness direction, and
the first corner terminal includes a first columnar portion that is a part of the first conductive layer.

6. The electronic device according to claim 5, wherein the conductive member includes a second conductive layer arranged between the first resin portion and the second resin portion in the thickness direction, and
the second conductive layer is electrically connected to the first conductive layer.

7. The electronic device according to claim 6, wherein the conductive member includes a third conductive layer formed on an opposite side from the first conductive layer relative to the second conductive layer in the thickness direction, and
the first corner terminal includes a second columnar portion that is a part of the third conductive layer.

8. The electronic device according to claim 7, wherein the first corner terminal includes an intervening portion that is a part of the second conductive layer and arranged between the first columnar portion and the second columnar portion.

9. The electronic device according to claim 7, wherein the first corner terminal has an exposed region exposed from the second columnar portion as viewed in the thickness direction.

10. The electronic device according to claim 9, wherein the exposed region is connected to the first surface as viewed in the thickness direction.

11. The electronic device according to claim 6, wherein the electronic component includes an element obverse surface and an element reverse surface spaced apart from each other in the thickness direction, and an electrode formed on the element obverse surface,
the element obverse surface faces the second conductive layer, and
the electrode is bonded to the second conductive layer.

12. The electronic device according to claim 3, wherein the first resin side surface faces a first side in a first direction perpendicular to the thickness direction, and
the second resin side surface faces a first side in a second direction perpendicular to the thickness direction and the first direction.

13. The electronic device according to claim 12, wherein the resin member includes a third resin side surface intersecting with the second resin side surface and facing away from the first resin side surface in the first direction, and a fourth resin side surface intersecting with the first resin side surface and facing away from the second resin side surface in the second direction, and
the third resin side surface and the fourth resin side surface intersect with each other.

14. The electronic device according to claim 13, the resin member includes a first resin recess recessed from the resin reverse surface and connected to the first resin side surface, a second resin recess recessed from the resin reverse surface and connected to the second resin side surface, a third resin recess recessed from the resin reverse surface and connected to the third resin side surface, and a fourth resin recess recessed from the resin reverse surface and connected to the fourth resin side surface.

15. The electronic device according to claim 13, wherein the conductive member includes a second corner terminal, a third corner terminal, and a fourth corner terminal exposed from the resin reverse surface,
the second corner terminal includes a third exposed surface exposed from the second resin side surface and a fourth exposed surface exposed from the third resin side surface,
the third corner terminal includes a fifth exposed surface exposed from the third resin side surface and a sixth exposed surface exposed from the fourth resin side surface, and
the fourth corner terminal includes a seventh exposed surface exposed from the fourth resin side surface and an eighth exposed surface exposed from the first resin side surface.

16. The electronic device according to claim 15, wherein the second corner terminal includes a second surface connected to the third exposed surface and the fourth exposed surface as viewed in the thickness direction and covered with the resin member,
the third corner terminal includes a third surface connected to the fifth exposed surface and the sixth exposed surface as viewed in the thickness direction and covered with the resin member, and
the fourth corner terminal includes a fourth surface connected to the seventh exposed surface and the eighth exposed surface as viewed in the thickness direction and covered with the resin member.

17. The electronic device according to claim 13, wherein the conductive member includes at least one side terminal exposed from one of the first resin side surface, the second resin side surface, the third resin side surface, and the fourth resin side surface.

18. The electronic device according to claim 17, wherein the at least one side terminal is electrically connected to the electronic component.

19. The electronic device according to claim 1, wherein the first corner terminal is electrically insulated from the electronic component.

20. The electronic device according to claim 1, wherein the electronic component is a semiconductor element made of a semiconductor material.
